(19) United States
(12) Patent Application Publication
(10) Pub. No.: US 2017/0365417 A1
(43) Pub. Date: Dec. 21, 2017

(54) PHOTOELECTRIC CONVERSION DEVICE AND PRODUCTION METHOD THEREOF

(71) Applicant: SUMITOMO CHEMICAL COMPANY, LIMITED, Tokyo (JP)

(72) Inventor: Yasunori UETANI, Tsukuba-shi (JP)

(73) Assignee: SUMITOMO CHEMICAL COMPANY, LIMITED, Tokyo (JP)

(21) Appl. No.: 15/544,347

(22) PCT Filed: Jan. 8, 2016
(86) PCT No.: PCT/JP2016/050438

§ 371 Date: Jul. 18, 2017

(30) Foreign Application Priority Data
Jan. 22, 2015 (JP) 2015-010029
Mar. 13, 2015 (JP) 2015-050387
Jun. 24, 2015 (JP) 2015-126294

(51) Int. Cl. H01G 9/20; H01L 51/00; H01L 51/44

(52) U.S. Cl. CPC H01G 9/2009; H01L 51/44; H01L 51/0043; H01L 51/0039; H01L 51/0003; H01L 51/0035; H01L 51/0031; H01L 51/0036

(57) ABSTRACT

Provided are a photoelectric conversion device giving high photoelectric conversion efficiency and a production method thereof. A photoelectric conversion device having an anode, a cathode, an active layer containing a perovskite compound disposed between the anode and the cathode, and a hole injection layer disposed between the anode and the active layer, wherein hole injection layer is a layer having a residual film rate of 80% or more in measurement of the residual film rate after a water rinse treatment, and the material of the hole injection layer is at least one material selected from the group consisting of polythiophene and derivatives thereof, aromatic amine compounds, and polymer compounds having an aromatic amine residue containing a phenyl group having at least three substituents as a repeating unit.

### TECHNICAL FIELD

The present invention relates to a photoelectric conversion device and a production method thereof.

### BACKGROUND ART

There is recently a suggestion on a photoelectric conversion device using a perovskite compound in an active layer.

For example, Non-patent document 1 describes a photoelectric conversion device in which a solution containing poly(3,4-ethylenedioxythiophene)/poly(4-styrenesulfonic acid) (PEDOT/PSS) is applied and a film is formed on ITO as a transparent electrode to forma hole injection layer, a solution containing a perovskite compound is applied and a film is formed on the hole injection layer to form an active layer, a solution containing a fullerene derivative [6,6]-phenylC₆₁-butyric acid methyl ester (C₆₀PCBM) is applied and a film is formed on the active layer to form an electron transporting layer, and a cathode material is vapor-deposited on the electron transporting layer to form a cathode.

### PRIOR ART DOCUMENT

### Non-Patent Document

Non-patent document 1: Journal of Material Chemistry A, 2014, No. 2, p. 15897

### SUMMARY OF THE INVENTION

### Problem to be Solved by the Invention

In the photoelectric conversion device of Non-patent document 1 described above, however, the resulting photoelectric conversion efficiency is not sufficient.

Then, the present invention has an object of providing a photoelectric conversion device by which high photoelectric conversion efficiency is obtained and a production method thereof.

### Means for Solving the Problem

That is, the present invention provides inventions according to the following [1] to [10].

[1] A photoelectric conversion device having an anode, a cathode, an active layer containing a perovskite compound disposed between the anode and the cathode, and a hole injection layer disposed between the anode and the active layer, wherein

the hole injection layer is a layer having a residual film rate of 80% or more in measurement of the residual film rate after a water rinse treatment shown below, and

the material of the hole injection layer is at least one material selected from the group consisting of polythiophene and derivatives thereof, aromatic amine compounds, and polymer compounds having an aromatic amine residue containing a phenyl group having at least three substituents as a repeating unit:

<Method of Measurement of Residual Film Rate after Water Rinse Treatment>

On a 1-inch square substrate, a film is formed by a spin coat method so at to give the same film thickness as in the case of film formation as the hole injection layer in the photoelectric conversion device, then, a water rinse treatment in which water is placed in the form of meniscus on the film, allowed to stand still for 30 seconds, then, the film is spun at 4000 rpm to fling away water is conducted.

The film thicknesses before and after the water rinse treatment are measured by a contact-type film thickness meter, and (film thickness after water rinse treatment)/(film thickness before water rinse treatment)×100(%) is defined as the residual film rate after the water rinse treatment.

[2] A photoelectric conversion device having an anode, a cathode, an active layer containing a perovskite compound disposed between the anode and the cathode, and a hole injection layer disposed between the anode and the active layer, wherein

the hole injection layer is a layer having a residual film rate of 80% or more in measurement of the residual film rate after the water rinse treatment shown above,

the material of the hole injection layer is at least one material selected from the group consisting of aromatic amine compounds and polymer compounds having an aromatic amine residue as a repeating unit, and

the thickness of the hole injection layer is 15 nm or less.

[3] The photoelectric conversion device according to [1] or [2], having a structure in which the supporting substrate, the anode, the hole injection layer, the active layer and the cathode are laminated in this order.

[4] The photoelectric conversion device according to any one of [1] to [3], further having an electron transporting layer disposed between the active layer and the cathode.

[5] The photoelectric conversion device according to [4], wherein the electron transporting layer is a layer formed by applying an application liquid containing at least one material selected from the group consisting of fullerenes and fullerene derivatives.

[6] The photoelectric conversion device according to any one of [1] to [5], further having a hole transporting layer disposed between the hole injection layer and the active layer.

[7] The photoelectric conversion device according to any one of [1] to [6], wherein the active layer is a layer formed by an application method.

[8] An organic optical sensor having the photoelectric conversion device according to any one of [1] to [7].

[9] A method of producing a photoelectric conversion device having a supporting substrate, an anode, a cathode, an active layer containing a perovskite compound disposed between the anode and the cathode, and a hole injection layer disposed between the anode and the active layer,

the method comprising

a step of forming a hole injection layer on an anode formed on a supporting substrate, and

a step of forming an active layer on the hole injection layer,

wherein

the hole injection layer is a layer having a residual film rate of 80% or more in measurement of the residual film rate after the water rinse treatment shown above, and

the material of the hole injection layer is at least one material selected from the group consisting of polythiophene and derivatives thereof, aromatic amine compounds, and polymer compounds having an aromatic amine residue containing a phenyl group having at least three substituents as a repeating unit.

[10] A method of producing a photoelectric conversion device having a supporting substrate, an anode, a cathode, an active layer containing a perovskite compound disposed between the anode and the cathode, and a hole injection layer disposed between the anode and the active layer,

the method comprising

a step of forming a hole injection layer on an anode formed on a supporting substrate, and

a step of forming an active layer on the hole injection layer,

wherein

the hole injection layer is a layer having a residual film rate of 80% or more in measurement of the residual film rate after the water rinse treatment shown above,

the material of the hole injection layer is at least one material selected from the group consisting of aromatic amine compounds and polymer compounds having an aromatic amine residue as a repeating unit, and

the thickness of the hole injection layer is 15 nm or less.

### Effect of the Invention

According to the present invention, a photoelectric conversion device using a perovskite compound in an active layer by which high photoelectric conversion efficiency is obtained and a production method thereof can be provided.

### MODES FOR CARRYING OUT THE INVENTION

The present invention will be illustrated in detail below.

### <1> Constitution of Photoelectric Conversion Device

The first embodiment of the photoelectric conversion device of the present invention is a photoelectric conversion device

having an anode, a cathode, an active layer containing a perovskite compound disposed between the anode and the cathode, and a hole injection layer disposed between the anode and the active layer, wherein

the hole injection layer is a layer having a residual film rate of 80% or more in measurement of the residual film rate after a water rinse treatment described later, and

the material of the hole injection layer is at least one material selected from the group consisting of polythiophene and derivatives thereof, aromatic amine compounds, and polymer compounds having an aromatic amine residue containing a phenyl group having at least three substituents as a repeating unit.

The second embodiment of the photoelectric conversion device of the present invention is a photoelectric conversion device

having an anode, a cathode, an active layer containing a perovskite compound disposed between the anode and the cathode, and a hole injection layer disposed between the anode and the active layer, wherein

the hole injection layer is a layer having a residual film rate of 80% or more in measurement of the residual film rate after a water rinse treatment described later,

the material of the hole injection layer is at least one material selected from the group consisting of aromatic amine compounds and polymer compounds having an aromatic amine residue as a repeating unit, and

the thickness of the hole injection layer is 15 nm or less.

In the present specification, the photoelectric conversion device of the present invention denotes both the first embodiment and the second embodiment of the photoelectric conversion device of the present invention.

The photoelectric conversion device of the present invention is preferably a photoelectric conversion device having a constitution in which a supporting substrate, an anode, a hole injection layer, an active layer and a cathode are laminated in this order, more preferably a photoelectric conversion device having a constitution in which a supporting substrate, an anode, a hole injection layer, an active layer, an electron transporting layer and a cathode are laminated in this order.

It is preferable that at least one of an anode and a cathode is transparent or semi-transparent. A perovskite compound contained in an active layer usually has a crystalline structure, and an incident light from a transparent or semi-transparent electrode is absorbed in the perovskite compound in the active layer, thereby generating electrons and holes. When electrons and holes transfer in the active layer, electric energy (current) is extracted outside.

### (Supporting Substrate)

The photoelectric conversion device of the present invention is usually formed on a supporting substrate. As the supporting substrate, those which do not chemically change in fabrication of a photoelectric conversion device are preferably used. The supporting substrate includes, for example, a glass substrate, a plastic substrate, a polymer film, a silicon plate and the like. In the case of a photoelectric conversion device wherein a light is incorporated from a transparent or opaque anode, a highly light-permeable substrate is suitably used as the supporting substrate. When a photoelectric conversion device is fabricated on an opaque supporting substrate, it is preferable that a cathode is constituted of a transparent or semi-transparent electrode since a light cannot be incorporated from the anode side. By using such an electrode, a light can be incorporated from a cathode opposite to an anode provided on the supporting substrate side, even if an opaque supporting substrate is used.

### (Anode)

As the anode, electrically conductive metal oxide films, metal films, electrically conductive films containing an organic substance, and the like are used. As the material of the anode, for example, indium oxide, zinc oxide, tin oxide, indium tin oxide (Indium Tin Oxide: abbreviated as ITO), fluorinated tin oxide (Fluorine Tin Oxide: abbreviated as FTO), indium zinc oxide (Indium Zinc Oxide: abbreviated as IZO), gold, platinum, silver, copper, aluminum, polyaniline and derivatives thereof, polythiophene and derivatives thereof, and the like are used. Of them, ITO, FTO, IZO and tin oxide are suitably used as the material of the anode. In the case of a photoelectric conversion device having a constitution of incorporating a light from an anode, a transparent or semi-transparent electrode obtained by adjusting the thickness of a film constituting an anode described above to a thickness permitting light permeation is usually used as the anode.

### (Hole Injection Layer)

The hole injection layer is disposed between an anode and an active layer, and has a function of promoting injection of holes into an anode. It is preferable that the hole injection layer is disposed in contact with an anode. In the photoelectric conversion device of the present invention, a material which is insoluble in water after film formation is used as the material of the hole injection layer. In the photoelectric conversion device of the present invention, the term “insoluble in water” denotes that the residual film rate is 80% or more, in measurement of the residual film rate after a water rinse treatment described later. The residual film rate is preferably 90% or more, further preferably 98% or more and 100% or less.

(Method of Measurement of Residual Film Rate after Water Rinse Treatment)

In the photoelectric conversion device of the present invention, the residual film rate after a water rinse treatment is determined by the following measurement method.

On a 1-inch square substrate, a film is formed by a spin coat method so at to give the same film thickness as in the case of film formation as the hole injection layer in the photoelectric conversion device, then, a water rinse treatment in which water is placed in the form of meniscus on the film, allowed to stand still for 30 seconds, then, the film is spun at 4000 rpm to fling away water is conducted.

The film thicknesses before and after the water rinse treatment are measured by a contact-type film thickness meter, and (film thickness after water rinse treatment)/(film thickness before water rinse treatment)×100(%) is defined as the residual film rate after the water rinse treatment.

In examples of the present specification, measurement of the film thicknesses before and after the water rinse treatment was conducted using a contact-type film thickness meter manufactured by DEKTAK Bruker Nano, as the contact-type film thickness meter.

The film for measurement of the residual film rate is a film which is substantially the same as the hole injection layer of the photoelectric conversion device of the present invention. More specifically, the film for measurement of the residual film rate is a film produced by using the substantially the same material as for the hole injection layer of the photoelectric conversion device of the present invention by substantially the same method as for the hole injection layer and having substantially the same thickness as that of the hole injection layer.

By placing water in the form of meniscus, namely, so that water forms meniscus, on the film for measurement of the residual film rate, water can be placed so as to cover substantially the whole surface of the film.

Spin for flinging away water is usually carried out by a spin coater. Flinging away of water is usually visually confirmed. Usually, the necessary time for flinging away water by spinning at 4000 rpm is 5 seconds or more.

The film thickness before the water rinse treatment and the film thickness after the water rinse treatment are usually measured at the center part of a film formed on a 1-inch square substrate.

The material of the hole injection layer which is insoluble in water after film formation includes polymer compounds such as polyaniline and derivatives thereof, polythiophene and derivatives thereof, polypyrrole and derivatives thereof, polymer compounds having an aromatic amine residue as a repeating unit, and the like, and low molecular weight compounds such as aniline, thiophene, pyrrole, aromatic amine compounds, and the like.

Of them, at least one material selected from the group consisting of polythiophene and derivatives thereof, aromatic amine compounds and polymer compounds having an aromatic amine residue as a repeating unit is preferable.

Of polymer compounds, polymer compounds having an aromatic amine residue as a repeating unit are preferable from the standpoint of long life.

The material of the hole injection layer in the first embodiment of the photoelectric conversion device of the present invention is preferably at least one material selected from the group consisting of polythiophene and derivatives thereof, aromatic amine compounds containing a phenyl group having at least three substituents and polymer compounds having an aromatic amine residue containing a phenyl group having at least three substituents as a repeating unit, more preferably at least one material selected from the group consisting of polythiophene and derivatives thereof and polymer compounds having an aromatic amine residue containing a phenyl group having at least three substituents as a repeating unit.

The material of the hole injection layer in the second embodiment of the photoelectric conversion device of the present invention is preferably a polymer compound having an aromatic amine residue as a repeating unit.

As the aromatic amine compound, those shown below are specifically exemplified.

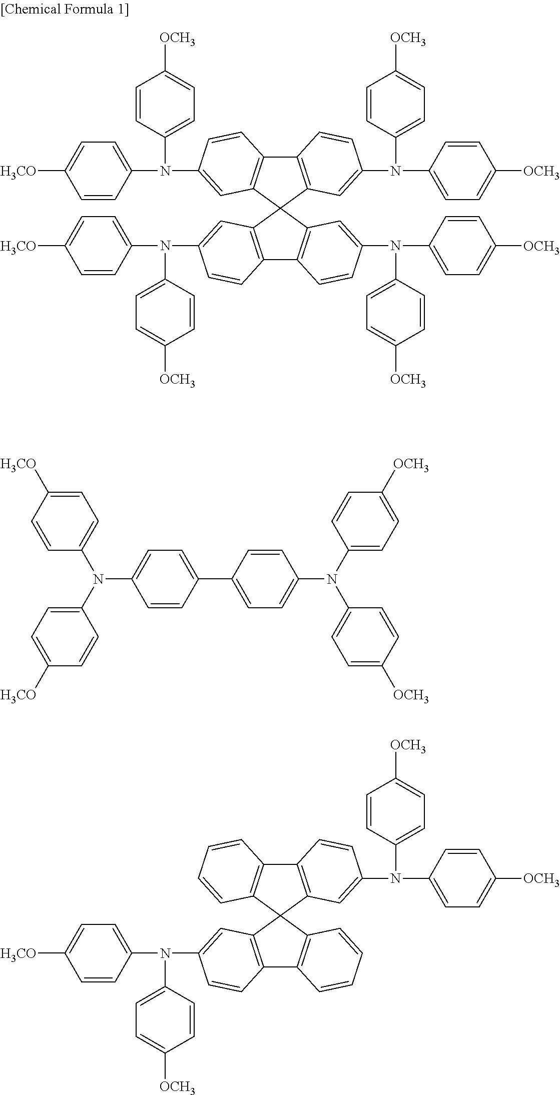 [SMILES: COc1ccc(N(c2ccc(OC)cc2)c2ccc3c(c2)C2(c4cc(N(c5ccc(OC)cc5)c5ccc(OC)cc5)ccc4-3)c3cc(N(c4ccc(OC)cc4)c4ccc(OC)cc4)ccc3-c3ccc(N(c4ccc(OC)cc4)c4ccc(OC)cc4)cc32)cc1 ; COc1ccc(N(c2ccc(OC)cc2)c2ccc(-c3ccc(N(c4ccc(OC)cc4)c4ccc(OC)cc4)cc3)cc2)cc1 ; COc1ccc(N(c2ccc(OC)cc2)c2ccc3c(c2)C2(c4ccccc4-3)c3ccccc3-c3ccc(N(c4ccc(OC)cc4)c4ccc(OC)cc4)cc32)cc1]

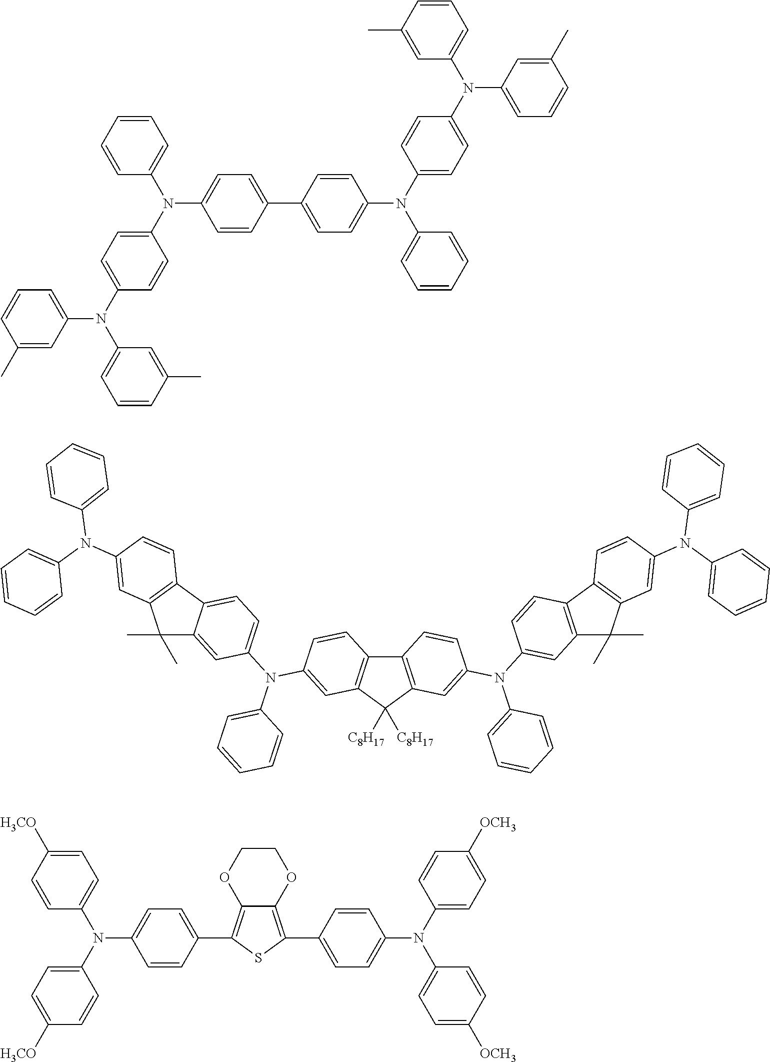

It is preferable that the aromatic amine compound contains a phenyl group having at least three substituents.

As the aromatic amine compound containing a phenyl group having at least three substituents, those shown below are specifically exemplified.

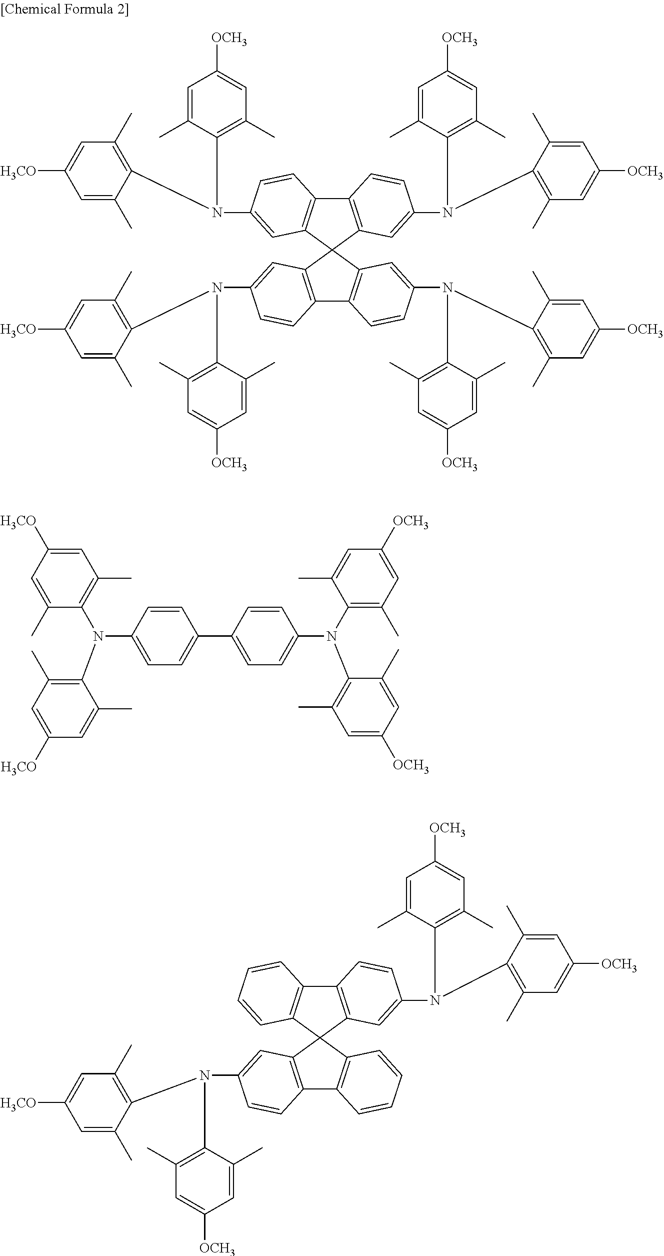 [SMILES: COc1cc(C)c(N(c2ccc3c(c2)C2(c4cc(N(c5c(C)cc(OC)cc5C)c5c(C)cc(OC)cc5C)ccc4-3)c3cc(N(c4c(C)cc(OC)cc4C)c4c(C)cc(OC)cc4C)ccc3-c3ccc(N(c4c(C)cc(OC)cc4C)c4c(C)cc(OC)cc4C)cc32)c2c(C)cc(OC)cc2C)c(C)c1 ; COc1cc(C)c(N(c2ccc(-c3ccc(N(c4c(C)cc(OC)cc4C)c4c(C)cc(OC)cc4C)cc3)cc2)c2c(C)cc(OC)cc2C)c(C)c1 ; COc1cc(C)c(N(c2ccc3c(c2)C2(c4ccccc4-3)c3ccccc3-c3ccc(N(c4c(C)cc(OC)cc4C)c4c(C)cc(OC)cc4C)cc32)c2c(C)cc(OC)cc2C)c(C)c1]

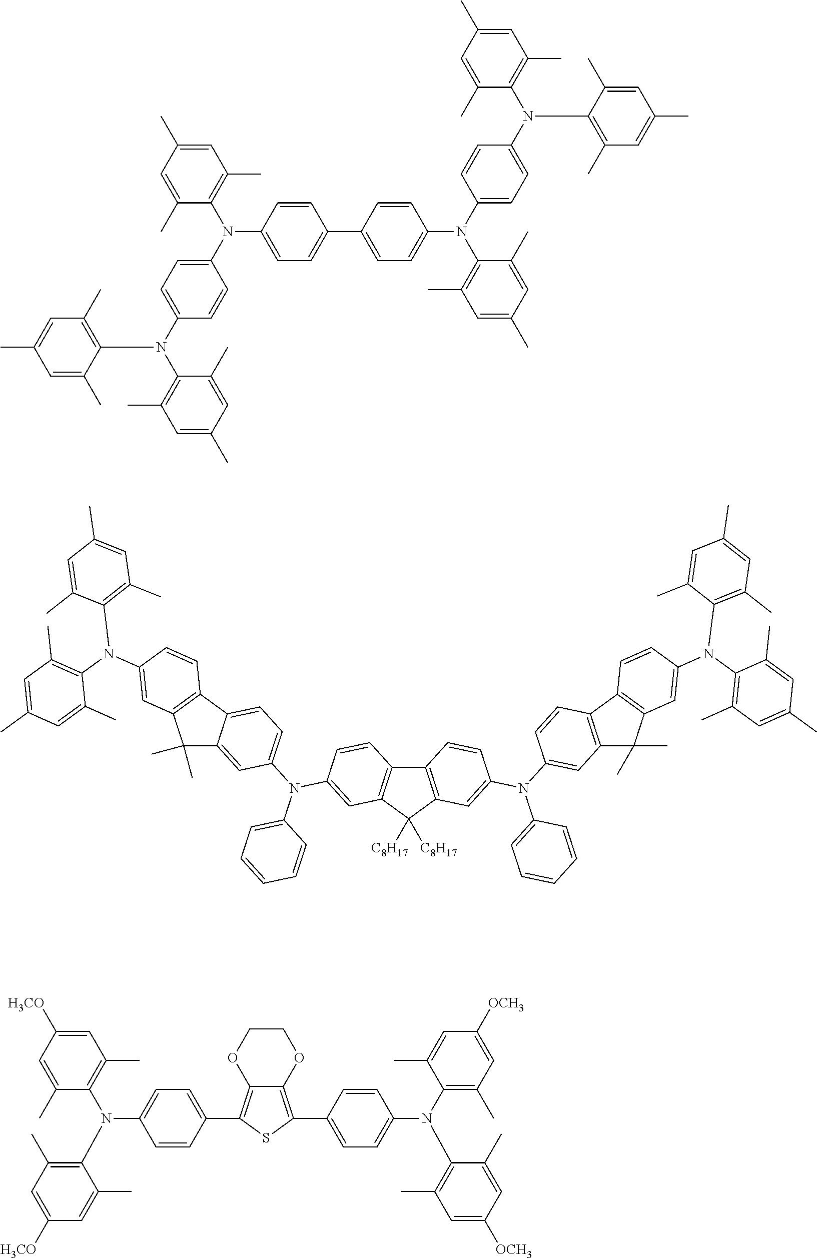

In the polymer compound having an aromatic amine residue as a repeating unit, the repeating unit having an aromatic amine residue is a repeating unit obtained by removing from an aromatic amine compound two hydrogen atoms. The repeating unit having an aromatic amine residue includes repeating units represented by the following formula (1). It is preferable that the polymer compound having an aromatic amine residue as a repeating unit contains a phenyl group having at least three substituents.

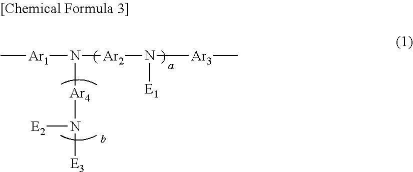

[wherein

Ar₁, Ar₂, Ar₃ and Ar₄ each independently represent an arylene group (A1) or a divalent heterocyclic group (B1).

E₁, E₂ and E₃ each independently represent an aryl group (A2) or a heterocyclic group (B2).

a and b each independently represent 0 or 1, and 0≦a+b≦1.

### Arylene Group (A1):

The arylene group is an atomic group remaining after removing from an aromatic hydrocarbon two hydrogen atoms, and includes those having a benzene ring or a condensed ring, and also those in which two or more rings selected from independent benzene rings and condensed rings are connected directly or via a group such as vinylene and the like. The arylene group may have a substituent. The substituent includes an alkyl group, an alkoxy group, an alkylthio group, an aryl group, an aryloxy group, an arylthio group, an arylalkyl group, an arylalkoxy group, an arylalkylthio group, an arylalkenyl group, an arylalkynyl group, an amino group, a substituted amino group, a silyl group, a substituted silyl group, a silyloxy group, a substituted silyloxy group, a halogen atom, an acyl group, an acyloxy group, an imine residue, an amide group, an acid imide group, a monovalent heterocyclic group, a carboxyl group, a substituted carboxyl group, a cyano group and the like, and an alkyl group, an alkoxy group, an alkylthio group, an aryl group, an aryloxy group, an arylthio group, a substituted amino group, a substituted silyl group, a substituted silyloxy group or a monovalent heterocyclic group is preferable. The number of carbon atoms of an unsubstituted arylene group (that is, the number of carbon atoms of an arylene group not including the number of carbon atoms of a substituent) is usually about 6 to 60, preferably 6 to 20.

### Divalent Heterocyclic Group (B1):

The divalent heterocyclic group is an atomic group remaining after removing from a heterocyclic compound two hydrogen atoms, and the divalent heterocyclic group may have a substituent. The heterocyclic compound includes organic compounds having a cyclic structure in which the ring constituent element includes not only a carbon atom but also hetero atoms such as oxygen, sulfur, nitrogen, phosphorus, boron, arsenic and the like contained in the ring. The substituent includes an alkyl group, an alkoxy group, an alkylthio group, an aryl group, an aryloxy group, an arylthio group, an arylalkyl group, an arylalkoxy group, an arylalkylthio group, an arylalkenyl group, an arylalkynyl group, an amino group, a substituted amino group, a silyl group, a substituted silyl group, a silyloxy group, a substituted silyloxy group, a halogen atom, an acyl group, an acyloxy group, an imino group, an amide group, an imide group, a monovalent heterocyclic group, a carboxyl group, a substituted carboxyl group, a cyano group and the like, and an alkyl group, an alkoxy group, an alkylthio group, an aryl group, an aryloxy group, an arylthio group, a substituted amino group, a substituted silyl group, a substituted silyloxy group or a monovalent heterocyclic group is preferable. The number of carbon atoms of an unsubstituted divalent heterocyclic group (that is, the number of carbon atoms of a divalent heterocyclic group not including the number of carbon atoms of a substituent) is usually about 3 to 60.

### Aryl Group (A2):

The aryl group may have a substituent selected from the group consisting of an alkyl group, an alkoxy group, an alkylthio group, an aryl group, an aryloxy group, an arylthio group, an arylalkyl group, an arylalkoxy group, an arylalkylthio group, an arylalkenyl group, an arylalkynyl group, an amino group, a substituted amino group, a silyl group, a substituted silyl group, a silyloxy group, a substituted silyloxy group, a monovalent heterocyclic group and a halogen atom. The number of carbon atoms of an unsubstituted aryl group (that is, the number of carbon atoms of an aryl group not including the number of carbon atoms of a substituent) is usually about 6 to 60, preferably 6 to 30.

### Monovalent Heterocyclic Group (B2):

The monovalent heterocyclic group may have a substituent selected from the group consisting of an alkyl group, an alkoxy group, an alkylthio group, an aryl group, an aryloxy group, an arylthio group, an arylalkyl group, an arylalkoxy group, an arylalkylthio group, an arylalkenyl group, an arylalkynyl group, an amino group, a substituted amino group, a silyl group, a substituted silyl group, a silyloxy group, a substituted silyloxy group, a monovalent heterocyclic group and a halogen atom. The number of carbon atoms of an unsubstituted monovalent heterocyclic group (that is, the number of carbon atoms of a monovalent heterocyclic group not including the number of carbon atoms of a substituent) is usually about 4 to 60.].

The aryl group (A2) is preferably an aryl group having three or more substituents, more preferably a phenyl group having three or more substituents, a naphthyl group having three or more substituents or an anthracenyl group having three or more substituents, further preferably a group represented by the following formula (2).

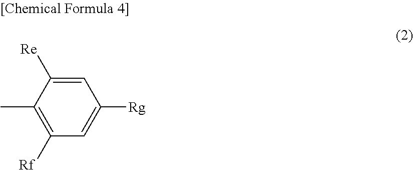

[wherein, Re, Rf and Rg each independently represent an alkyl group, an alkoxy group, an alkylthio group, an aryl group, an aryloxy group, an arylthio group, an arylalkyl group, an arylalkoxy group, an arylalkylthio group, an arylalkenyl group, an arylalkynyl group, an amino group, a substituted amino group, a silyl group, a substituted silyl group, a silyloxy group, a substituted silyloxy group, a monovalent heterocyclic group or a halogen atom.].

The polymer compound having an aromatic amine residue as a repeating unit may further have a repeating unit represented by the formula (3), the formula (4), the formula (5) or the formula (6) described below.

—Ar₁₂— (3)

—Ar₁₂—X—(Ar₁₃—X₂)_{c}—Ar₁₄— (4)

—Ar₁₂-X₂— (5)

—X₂— (6)

[wherein,

Ar₁₂, Ar₁₃ and Ar₁₄ each independently represent an arylene group, a divalent heterocyclic group or a divalent group having a metal complex structure.

X₁ represents —CR₂═CR₃—, —C═C— or (SiR₅R₆)_{d}—.

X₂ represents —CR₂═CR₃—, —C═C—, —N(R₄)— or (SiR₅R₆)_{d}—.

R₂ and R₃ each independently represent a hydrogen atom, an alkyl group, an aryl group, a monovalent heterocyclic group, a carboxyl group, a substituted carboxyl group or a cyano group.

R₄, R₅ and R₆ each independently represent a hydrogen atom, an alkyl group, an aryl group, a monovalent heterocyclic group or an arylalkyl group.

c represents an integer of 0 to 2. d represents an integer of 1 to 12.

When a plurality of Ar₁₃, R₂, R₃, R₅ and R₆ are present, they may be the same or different at each occurrence.].

The repeating units represented by the formula (1) in which Ar₁, Ar₂, Ar₃ and Ar₄ are unsubstituted phenylene groups, a=1 and b=0 include, specifically, those shown below.

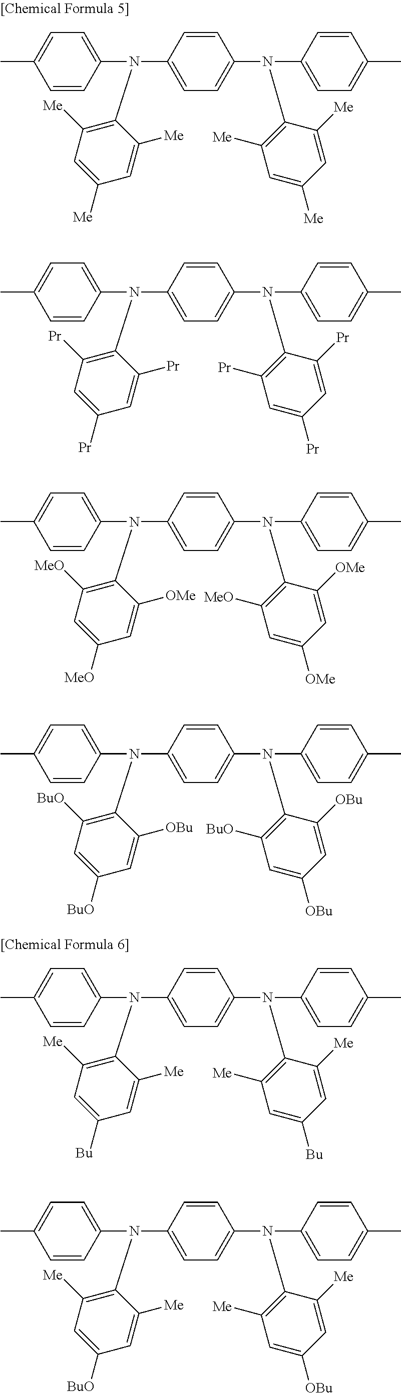

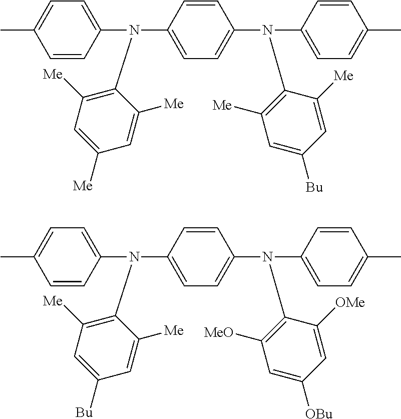

The repeating units represented by the formula (1) in which Ar₁, Ar₂, Ar₃ and Ar₄ are unsubstituted phenylene groups, a=0 and b=1 include, specifically, those shown below.

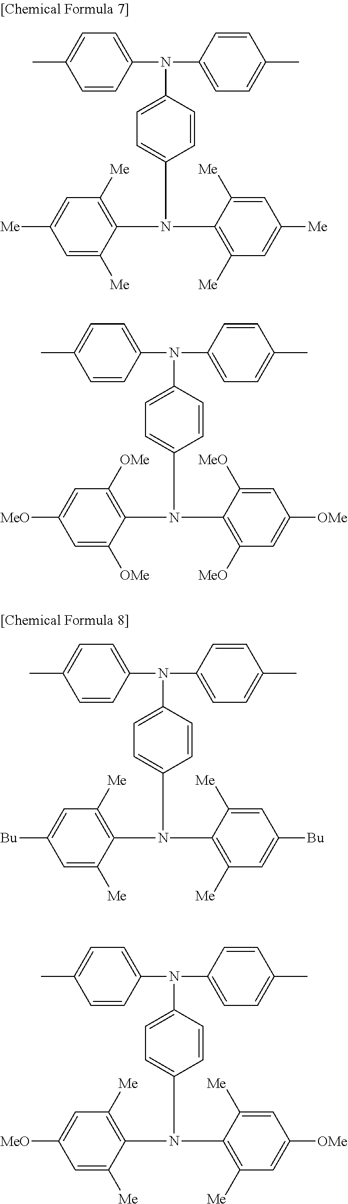

In the above-described formulae, Me represents a methyl group, Pr represents a propyl group, Bu represents a butyl group, MeO represents a methoxy group and BuO represents a butyloxy group, respectively.

In the first embodiment of the photoelectric conversion device of the present invention, thickness of a hole injection layer is preferably 15 nm or less, more preferably 10 nm or less, from the standpoint of obtaining higher photoelectric conversion efficiency. In the second embodiment of the photoelectric conversion device of the present invention, thickness of a hole injection layer is preferably 10 nm or less, from the standpoint of obtaining higher photoelectric conversion efficiency.

It is preferable that the hole injection layer is formed by an application method. The application liquid used in the application method contains a solvent and the material of the hole injection layer. The solvent includes, for example, water, alcohols, ketones, hydrocarbons and the like. Specific examples of the alcohol include methanol, ethanol, isopropanol, butanol, ethylene glycol, propylene glycol, butoxyethanol, methoxybutanol and the like. Specific examples of the ketone include acetone, methyl ethyl ketone, methyl isobutyl ketone, 2-heptanone, cyclohexanone and the like. Specific examples of the hydrocarbon include n-pentane, cyclohexane, n-hexane, benzene, toluene, xylene, tetralin, chlorobenzene, orthodichlorobenzene and the like. The application liquid may contain one kind of solvent singly or may contain two or more kinds of solvents, and may contain two or more kinds of the solvents exemplified above. The amount of the solvent is preferably 1 time by weight or more and 10000 times by weight or less, more preferably 10 times by weight or more and 1000 times by weight or less per weight of the material of the hole injection layer.

### (Hole Transporting Layer)

The hole transporting layer is disposed between a hole injection layer and an active layer and has a function of blocking electrons. By providing the hole transporting layer, a photoelectric conversion device showing higher photoelectric conversion efficiency can be obtained. The material of the hole transporting layer includes, for example, aromatic amine compounds, polymer compounds having an aromatic amine residue as a repeating unit, and the like. When aromatic amine compounds and polymer compounds having an aromatic amine residue as a repeating unit are used as the material of the hole injection layer, the hole transporting layer may not be provided.

It is preferable that the hole transporting layer is formed by an application method. The application liquid used in the application method contains a solvent and the material of the hole transporting layer. The solvent includes, for example, water, alcohols, ketones, hydrocarbons and the like. Specific examples of the alcohol include methanol, ethanol, isopropanol, butanol, ethylene glycol, propylene glycol, butoxyethanol, methoxybutanol and the like. Specific examples of the ketone include acetone, methyl ethyl ketone, methyl isobutyl ketone, 2-heptanone, cyclohexanone and the like. Specific examples of the hydrocarbon include n-pentane, cyclohexane, n-hexane, benzene, toluene, xylene, tetralin, chlorobenzene, orthodichlorobenzene and the like. The application liquid may contain one kind of solvent singly or may contain two or more kinds of solvents, and may contain two or more kinds of the solvents exemplified above. The amount of the solvent is preferably 1 time by weight or more and 10000 times by weight or less, more preferably 10 times by weight or more and 1000 times by weight or less per weight of the material of the hole transporting layer.

### (Active Layer)

The active layer contains a perovskite compound. It is preferable that the perovskite compound is a perovskite compound having an organic inorganic hybrid structure. The perovskite compound in the photoelectric conversion device of the present invention includes preferably compounds represented by the following formula (7) or (8), more preferably compounds of the formula (7). Of compounds represented by the formula (7), CH₃NH₃PbI₃, CH₃NH₃PbCl₃, CH₃NH₃PbBr₃, CH₃NH₃SnI₃, CH₃NH₃SnCl₃, CH₃NH₃SnBr₃ and the like are more preferable.

CH₃NH₃M₁X₃ (7)

[wherein,

M₁ represents a divalent metal (for example, Cu, Ni, Mn, Fe, Co, Pd, Ge, Sn, Pb or Eu).

X represents F, Cl, Br or I.].

(R₁NH₃)₂M₁X₄ (8)

[wherein,

R₁ represents an alkyl group having a number of carbon atoms of 2 or more, an alkenyl group, an aralkyl group, an aryl group or a monovalent heterocyclic group (preferably a monovalent aromatic heterocyclic group).

M₁ represents a divalent metal (for example, Cu, Ni, Mn, Fe, Co, Pd, Ge, Sn, Pb or Eu).

X represents F, Cl, Br or I.].

### (Electron Transporting Layer)

It is preferable that the photoelectric conversion device of the present invention has an electron transporting layer disposed between an active layer and a cathode.

It is preferable that the electron transporting layer is formed by an application method. The application liquid used in the application method contains a solvent and an electron transportable material. It is preferable that the electron transporting layer is formed by applying an application liquid containing an electron transportable material and a solvent on an active layer. The application liquid may be a dispersion such as an emulsion (milky juice), a suspension (suspending solution) and the like. As the application liquid, those imparting little damage on a layer (an active layer and the like) on which the application liquid is applied are preferable, and specifically, those scarcely dissolve a layer (an active layer and the like) on which the application liquid is applied are preferable.

The electron transportable material may be an organic compound or an inorganic compound.

The electron transportable material as an organic compound may be a low molecular weight organic compound or a polymer organic compound. The electron transportable material as a low molecular weight organic compound includes, for example, oxadiazole derivatives, anthraquinodimethane and derivatives thereof, benzoquinone and derivatives thereof, naphthoquinone and derivatives thereof, anthraquinone and derivatives thereof, tetracyanoanthraquinodimethane and derivatives thereof, fluorenone derivatives, diphenyldicyanoethylene and derivatives thereof, diphenoquinone derivatives, metal complexes of 8-hydroxyquinoline and derivatives thereof, polyquinoline and derivatives thereof, polyquinoxaline and derivatives thereof, polyfluorene and derivatives thereof, fullerenes such as C₆₀ and the like and derivatives thereof, phenanthrene derivatives such as bathocuproine and the like; etc. The electron transportable material as a polymer organic compound includes, for example, polyvinyl carbazole and derivatives thereof, polysilane and derivatives thereof, polysiloxane derivatives having an aromatic amine in the side chain or main chain, polyanilines and derivatives thereof, polythiophene and derivatives thereof, polypyrrole and derivatives thereof, polyphenylenevinylene and derivatives thereof, polythienylenevinylene and derivatives thereof, polyfluorene and derivatives thereof, and the like. Of them, fullerenes and derivatives thereof are preferable.

Fullerenes include C₆₀ fullerene, C₇₀ or higher fullerene, carbon nanotubes, and derivatives thereof. Specific examples of derivatives of C₆₀ fullerene include those shown below.

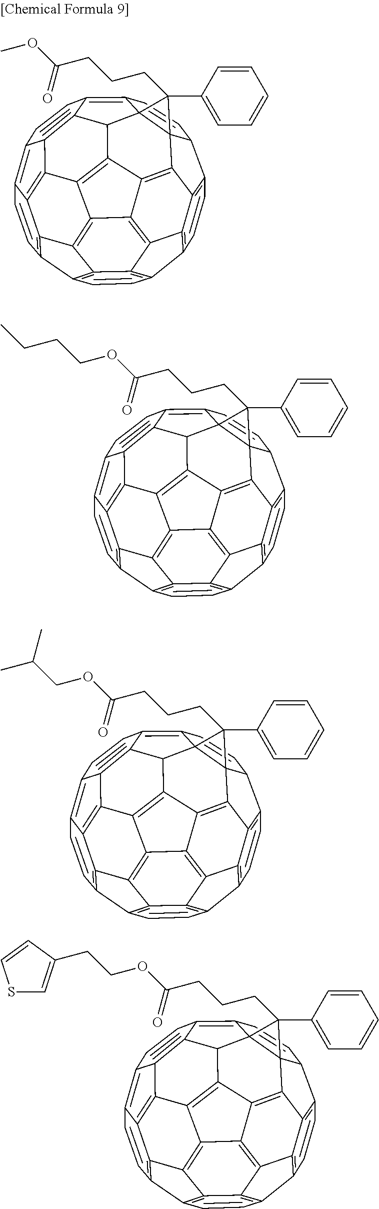

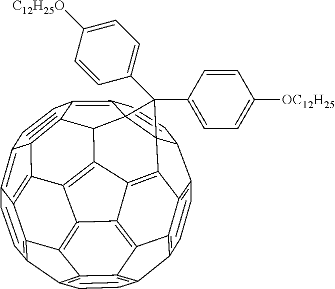

The electron transportable material as an inorganic compound includes, for example, zinc oxide, titanium oxide, zirconium oxide, tin oxide, indium oxide, GZO (gallium-doped zinc oxide), ATO (antimony-doped tin oxide) and AZO (aluminum-doped zinc oxide). Of them, zinc oxide, gallium-doped zinc oxide or aluminum-doped zinc oxide is preferable. In forming an electron transporting layer, it is preferable that an application liquid containing granular zinc oxide, gallium-doped zinc oxide or aluminum-doped zinc oxide is used to form the electron transporting layer. Regarding the electron transportable material as described above, nanoparticles of zinc oxide, nanoparticles of gallium-doped zinc oxide or nanoparticles of aluminum-doped zinc oxide are preferably used, and it is more preferable to form an electron transporting layer using an electron transportable material composed only of nanoparticles of zinc oxide, nanoparticles of gallium-doped zinc oxide or nanoparticles of aluminum-doped zinc oxide. The sphere-equivalent average particle size of nanoparticles of zinc oxide, nanoparticles of gallium-doped zinc oxide or nanoparticles of aluminum-doped zinc oxide is preferably 1 nm to 1000 nm, more preferably 10 nm to 100 nm. The average particle size can be measured by a laser light scattering method, an X-ray diffraction method and the like.

The solvent contained in the application liquid containing the electron transportable material (organic compound and inorganic compound) includes, for example, alcohols, ketones, hydrocarbons and the like. Specific examples of the alcohol include methanol, ethanol, isopropanol, butanol, ethylene glycol, propylene glycol, butoxyethanol, methoxybutanol and the like. Specific examples of the ketone include acetone, methyl ethyl ketone, methyl isobutyl ketone, 2-heptanone, cyclohexanone and the like. Specific examples of the hydrocarbon include n-pentane, cyclohexane, n-hexane, benzene, toluene, xylene, tetralin, chlorobenzene, orthodichlorobenzene and the like. The application liquid may contain one kind of solvent singly or may contain two or more kinds of solvents, and may contain two or more kinds of the solvents exemplified above. The amount of the solvent is preferably 1 time by weight or more and 10000 times by weight or less, more preferably 10 times by weight or more and 1000 times by weight or less per weight of the electron transportable material.

It is preferable that the application liquid containing a solvent and an electron transportable material is filtrated through a Teflon (registered trademark) filter having a pore diameter of 0.5 μm, and the like.

### (Cathode)

The cathode may take a single-layer configuration or a configuration of lamination of a plurality of layers. As the material of the cathode, metals, electrically conductive polymers and the like can be used. As the material of the cathode, for example, metals such as lithium, sodium, potassium, rubidium, cesium, magnesium, calcium, strontium, barium, aluminum, scandium, vanadium, zinc, yttrium, indium, cerium, samarium, europium, terbium, ytterbium, gold, silver, platinum, copper, manganese, titanium, cobalt, nickel, tungsten, tin and the like; alloys containing two or more metals selected from the group consisting of these metals; graphite, graphite intercalation compounds and the like are used. The alloy includes, for example, a magnesium silver alloy, a magnesium indium alloy, a magnesium aluminum alloy, an indium silver alloy, a lithium aluminum alloy, a lithium magnesium alloy, a lithium indium alloy, a calcium aluminum alloy and the like.

The material of the transparent or semi-transparent cathode includes, for example, electrically conductive metal oxide films, semi-transparent metal films and the like.

Specifically, electrically conductive materials such as indium oxide, zinc oxide, tin oxide, composites thereof: indium.tin.oxide (ITO), indium.zinc.oxide and the like; NESA, gold, platinum, silver and copper are listed. Of them, electrically conductive materials such as ITO, indium.zinc.oxide, tin oxide and the like are preferable.

The cathode fabrication method includes, for example, a vacuum vapor deposition method, a sputtering method, an ion plating method, a plating method, an application method and the like.

The application liquid used in forming the cathode by an application method includes an emulsion (milky juice), a suspension (suspending solution) and the like containing nanoparticles of an electrically conductive substance, nanowires of an electrically conductive substance or nanotubes of an electrically conductive substance and a solvent. The electrically conductive substance includes metals such as gold, silver and the like; oxides such as ITO (indium tin oxide) and the like; carbon nanotubes and the like.

The cathode may be constituted only of nanoparticles of an electrically conductive substance or nanowires of an electrically conductive substance, or may have a constitution in which nanoparticles of an electrically conductive substance or nanowires of an electrically conductive substance are dispersed in a prescribed medium such as an electrically conductive polymer and the like as described in Japanese Patent Application National Publication No. 2010-525526.

The solvent contained in the application liquid used in forming the cathode by an application method includes, for example, hydrocarbon solvents such as toluene, xylene, mesitylene, tetralin, decalin, bicyclohexyl, n-butylbenzene, s-butylbenzene, t-butylbenzene and the like; halogenated saturated hydrocarbon solvents such as carbon tetrachloride, chloroform, dichloromethane, dichloroethane, chlorobutane, bromobutane, chloropentane, bromopentane, chlorohexane, bromohexane, chlorocyclohexane, bromocyclohexane and the like; halogenated unsaturated hydrocarbon solvents such as chlorobenzene, dichlorobenzene, trichlorobenzene and the like; ether solvents such as tetrahydrofuran, tetrahydropyran and the like; water, alcohols and the like. Specific examples of the alcohol include methanol, ethanol, isopropanol, butanol, ethylene glycol, propylene glycol, butoxyethanol, methoxybutanol and the like. The application liquid may contain one kind of solvent singly or may contain two or more kinds of solvents, and may contain two or more kinds of the solvents exemplified above.

### <2> Production Method of Photoelectric Conversion Device

The first embodiment of the production method of the photoelectric conversion device of the present invention is

a method of producing a photoelectric conversion device having a supporting substrate, an anode, a cathode, an active layer containing a perovskite compound disposed between the anode and the cathode, and a hole injection layer disposed between the anode and the active layer,

the method comprising

a step of forming a hole injection layer on an anode formed on a supporting substrate, and

a step of forming an active layer on the hole injection layer,

wherein

the hole injection layer is a layer having a residual film rate of 80% or more in measurement of the residual film rate after the water rinse treatment described above, and

the material of the hole injection layer is at least one material selected from the group consisting of polythiophene and derivatives thereof, aromatic amine compounds, and polymer compounds having an aromatic amine residue containing a phenyl group having at least three substituents as a repeating unit.

The second embodiment of the production method of the photoelectric conversion device of the present invention is

a method of producing a photoelectric conversion device having a supporting substrate, an anode, a cathode, an active layer containing a perovskite compound disposed between the anode and the cathode, and a hole injection layer disposed between the anode and the active layer,

the method comprising

a step of forming a hole injection layer on an anode formed on a supporting substrate, and

a step of forming an active layer on the hole injection layer,

wherein

the hole injection layer is a layer having a residual film rate of 80% or more in measurement of the residual film rate after the water rinse treatment described above,

the material of the hole injection layer is at least one material selected from the group consisting of aromatic amine compounds and polymer compounds having an aromatic amine residue as a repeating unit, and

the thickness of the hole injection layer is 15 nm or less.

In the present specification, the production method of the photoelectric conversion device of the present invention denotes both the first embodiment and the second embodiment of the production method of the photoelectric conversion device of the present invention.

### <Formation Step of Anode>

The anode can be formed by film-forming the material of the anode described above on a supporting substrate by a vacuum vapor deposition method, a sputtering method, an ion plating method, a plating method and the like. When organic materials such as polyanilines and derivatives thereof, polythiophene and derivatives thereof and the like are used as the material of the anode, the anode may be formed by an application method using an application liquid containing an organic material. The anode may also be formed by an application method using a metal ink, a metal paste, a low melting point metal in molten state or the like. The anode may be subjected to a surface treatment such as an ozone UVtreatment, a corona treatment, an ultrasonic wave treatment and the like.

### <Formation Step of Hole Injection Layer>

The formation method of the hole injection layer is not particularly restricted, and it is preferable that the hole injection layer is formed by an application method from the standpoint of simplification of the production step. The hole injection layer can be formed, for example, by applying an application liquid containing the material of the hole injection layer described above and a solvent.

The method of applying an application liquid containing the material of the hole injection layer and a solvent includes, for example, a spin coat method, a casting method, a micro gravure coat method, a gravure coat method, a bar coat method, a roll coat method, a wire bar coat method, a dip coat method, a spray coat method, a screen printing method, a flexo printing method, an offset printing method, an inkjet printing method, a dispenser printing method, a nozzle coat method, a capillary coat method and the like. Of them, a spin coat method, a flexo printing method, an inkjet printing method and a dispenser printing method are preferable.

It is preferable that after applying an application liquid containing the material of the hole injection layer and a solvent, the applied film is subjected to a heating treatment, an air drying treatment, a pressure-reducing treatment and the like, to remove a solvent.

### <Formation Step of Hole Transporting Layer>

The production method of the photoelectric conversion device of the present invention may further contain a step of forming a hole transporting layer disposed between a hole injection layer and an active layer.

The formation method of the hole transporting layer is not particularly restricted, and it is preferable that the hole transporting layer is formed by an application method from the standpoint of simplification of the production step. The hole transporting layer can be formed, for example, by applying an application liquid containing the material of the hole transporting layer described above and a solvent.

The method of applying an application liquid containing the material of the hole transporting layer and a solvent includes, for example, a spin coat method, a casting method, a micro gravure coat method, a gravure coat method, a bar coat method, a roll coat method, a wire bar coat method, a dip coat method, a spray coat method, a screen printing method, a flexo printing method, an offset printing method, an inkjet printing method, a dispenser printing method, a nozzle coat method, a capillary coat method and the like. Of them, a spin coat method, a flexo printing method, an inkjet printing method and a dispenser printing method are preferable.

### <Formation Step of Active Layer>

The formation method of the active layer is not particularly restricted, and it is preferable that the active layer is formed by an application method from the standpoint of simplification of the production step. The active layer can be formed, for example, by applying an application liquid containing the perovskite compound described above and a solvent. The perovskite compound can be synthesized by a self-organization reaction using a precursor solution.

The active layer formation method other than the above-described methods includes

a method in which an application liquid containing a metal halide and a solvent is applied, then, an application liquid containing an ammonium halide and a solvent or an application liquid containing a halogenated amine and a solvent is applied on the film of the metal halide, or

a method in which an application liquid containing a metal halide and a solvent is applied, then, the film of the metal halide is immersed in an application liquid containing an ammonium halide and a solvent or an application liquid containing a halogenated amine and a solvent.

That is, the active layer can be formed, for example, by applying an application liquid containing lead iodide and a solvent on a hole injection layer or a hole transporting layer, then, applying an application liquid containing methylammonium iodide and a solvent on the film of lead iodide.

The amount of the solvent is preferably 1 time by weight or more and 10000 times by weight or less, more preferably 10 times by weight or more and 1000 times by weight or less per weight of a metal halide, an ammonium halide or a halogenated amine.

It is preferable that after each of the application steps described above, the applied film is subjected to a heating treatment, an air drying treatment, a pressure-reducing treatment and the like, to remove a solvent.

The solvent contained in the application liquid used in forming the active layer by an application method includes, for example, esters (for example, methyl formate, ethyl formate, propyl formate, pentyl formate, methyl acetate, ethyl acetate, pentyl acetate and the like), ketones (for example, γ-butyrolactone, N-methyl-2-pyrrolidone, acetone, dimethyl ketone, diisobutyl ketone, cyclopentanone, cyclohexanone, methylcyclohexanone and the like), ethers (for example, diethyl ether, methyl tert-butyl ether, diisopropyl ether, dimethoxymethane, dimethoxyethane, 1,4-dioxane, 1,3-dioxolane, 4-methyldioxolane, tetrahydrofuran, methyltetrahydrofuran, anisole, phenetole and the like), alcohols (for example, methanol, ethanol, 1-propanol, 2-propanol, 1-butanol, 2-butanol, tert-butanol, 1-pentanol, 2-methyl-2-butanol, methoxypropanol, diacetone alcohol, cyclohexanol, 2-fluoroethanol, 2,2,2-trifluoroethanol, 2,2,3,3-tetrafluoro-1-propanol and the like), glycol ethers (cellosolves) (for example, ethylene glycol monomethyl ether, ethylene glycol monoethyl ether, ethylene glycol monobutyl ether, ethylene glycol monoethyl ether acetate, triethylene glycol dimethyl ether and the like), amide solvents (for example, N,N-dimethylformamide, acetamide, N,N-dimethylacetamide and the like), nitrile solvents (for example, acetonitrile, isobutyronitrile, propionitrile, methoxyacetonitrile and the like), carbonate solvents (for example, ethylene carbonate, propylene carbonate and the like), halogenated hydrocarbons (for example, methylene chloride, dichloromethane, chloroform and the like), hydrocarbons (for example, n-pentane, cyclohexane, n-hexane, benzene, toluene, xylene and the like), dimethyl sulfoxide, and the like. These solvents may have a branched structure or a cyclic structure. These solvents may have any two or more of functional groups of esters, ketones, ethers and alcohols (namely, —O—, —CO—, —COO—, —OH). A hydrogen atom in a hydrocarbon portion of esters, ketones, ethers and alcohols may be substituted by a halogen atom (particularly, a fluorine atom). The application liquid may contain one kind of solvent singly or may contain two or more kinds of solvents, and may contain two or more kinds of the solvents exemplified above.

The method of applying an application liquid containing a perovskite compound and a solvent, a solution containing a metal halide and a solvent, a solution containing an ammonium halide and a solvent and a solution containing a halogenated amine and solvent includes, for example, a spin coat method, a casting method, a micro gravure coat method, a gravure coat method, a bar coat method, a roll coat method, a wire bar coat method, a dip coat method, a spray coat method, a screen printing method, a flexo printing method, an offset printing method, an inkjet printing method, a dispenser printing method, a nozzle coat method, a capillary coat method, and the like. Of them, a spin coat method, a flexo printing method, an inkjet printing method and a dispenser printing method are preferable.

### <Formation Step of Electron Transporting Layer>

The production method of the photoelectric conversion device of the present invention may further contain a step of forming an electron transporting layer disposed between an active layer and a cathode.

The formation method of the electron transporting layer is not particularly restricted, and it is preferable that the electron transporting layer is formed by an application method from the standpoint of simplification of the production step. That is, it is preferable to form the electron transporting layer by applying an application liquid containing the electron transportable material described above and a solvent on an active layer, after formation of the active layer and before formation of a cathode. As the application method of the application liquid containing the electron transportable material and a solvent, the same application method as exemplified for the formation step of the active layer is mentioned.

### <Formation Step of Cathode>

The cathode can be formed by film-forming the material of the cathode described above on an active layer or an electron transporting layer by a vacuum vapor deposition method, a sputtering method, an ion plating method, a plating method, an application method and the like. When the materials of the cathode are polyaniline and derivatives thereof, polythiophene and derivatives thereof, nanoparticles of an electrically conductive substance, nanowires of an electrically conductive substance or nanotubes of an electrically conductive substance, the cathode can be formed by an application method using an emulsion (milky juice), a suspension (suspending solution) and the like containing these materials and a solvent. When the materials of the cathode contain an electrically conductive substance, the cathode may be formed by an application method using an application liquid containing an electrically conductive substance, a metal ink, a metal paste, a low melting point metal in molten state or the like. As the application method of the application liquid containing the material of the cathode and a solvent, the same application method as exemplified for the formation step of the active layer is mentioned.

The photoelectric conversion device of the present invention can be operated as a solar battery since photovoltaic power is generated between electrodes when a transparent or semi-transparent electrode is irradiated with a light such as a solar light and the like. The solar battery is preferably an organic inorganic perovskite solar battery. By integrating a plurality of solar batteries, a film solar battery module can be obtained.

The photoelectric conversion device of the present invention can be operated as an organic optical sensor since photocurrent flows when a transparent or semi-transparent electrode is irradiated with a light under condition of application of voltage between electrodes. By integrating a plurality of organic optical sensors, an image sensor can be obtained.

### EXAMPLES

Examples will be shown below for illustrating the present invention further in detail, but the present invention is not limited to them.

The polystyrene-equivalent number-average molecular weight was determined by gel permeation chromatography (GPC) under the following conditions.

Column: TOSOH TSKgel SuperHM-H (two columns)+TSKgel SuperH2000 (4.6 mm I.d.×15 cm)

Detector: RI (SHIMADZU RID-10A)

Mobile phase: chloroform or tetrahydrofuran (THF)

### Synthesis Example 1 (Synthesis of Polymer Compound 1)

bis(4-bromophenyl)-4-sec-butylphenylamine (6.2 g) and 2, 2′-bipyridyl (5.6 g) were added into a reaction vessel, then, a gas in the reaction system was purged with a nitrogen gas, and tetrahydrofuran (dehydrated solvent) (400 g) was added. Next, to this mixed solution was added bis(1,5-cyclooctadiene)nickel (0) (10 g), then, the mixture was reacted at room temperature for 24 hours. This reaction was conducted in a nitrogen gas atmosphere. The mixed solution obtained after the reaction was poured into a mixed solution of methanol (200 ml) and ion exchanged water (200 ml), and the mixture was stirred. The deposited precipitate was recovered by filtration, and dried. Next, this precipitate was dissolved in toluene, unwanted substances were removed through a paper filter, then, the resultant filtrate was treated by an aluminum column. To the resultant toluene solution was added ammonia water and the liquid was stirred, an aqueous layer was removed, then, ion exchanged water was added and the mixture was stirred, and an aqueous layer was removed. The resultant organic layer was dropped into methanol and the mixture was stirred, then, the deposited precipitate was filtrated, and dried under reduce pressure, to obtain a polymer compound 1 (0.6 g).

The polymer compound 1 had a polystyrene-equivalent weigh-average molecular weight of 14000 and a Mw/Mn=2.7.

### Synthesis Example 2 (Synthesis of Polymer Compound 2)

N,N′-bis(4-bromophenyl)-N,N′-bis(4-tert-butyl2,6-dimeth ylphenyl)-1,4-phenylenediamine (11.1 g) and 2, 2′-bipyridyl (5.6 g) were added into a reaction vessel, then, a gas in the reaction system was purged with a nitrogen gas, and tetrahydrofuran (dehydrated solvent) (400 g) was added. Next, to this mixed solution was added bis(1,5-cyclooctadiene)nickel(0) (10 g), then, the mixture was reacted at 60° C. for 3 hours. This reaction was conducted in a nitrogen gas atmosphere. The solution obtained after the reaction was cooled, then, poured into a mixed solution of 25% ammonia water (50 ml), methanol (200 ml) and ion exchanged water (200 ml), and the mixture was stirred. The deposited precipitate was recovered by filtration, and dried under reduced pressure. Next, this precipitate was dissolved in toluene, unwanted substances were removed through a paper filter, then, the resultant filtrate was treated by an aluminum column. To the resultant toluene solution was added 1 N hydrochloric acid water and the mixture was stirred, an aqueous layer was removed, then, 3′ ammonia water was added and the mixture was stirred, an aqueous layer was removed, then, ion exchanged water was added and the mixture was stirred, and an aqueous layer was removed. The resultant organic layer was dropped into methanol and the mixture was stirred, then, the deposited precipitate was filtrated, and dried under reduce pressure, to obtain a polymer compound 2 (4.7 g).

The polymer compound 2 had a polystyrene-equivalent weigh-average molecular weight of 45000 and a Mw/Mn=6.7.

### (Production of Composition 1)

Lead iodide (460 mg) was dissolved in 1 ml of N,N-dimethylformamide, then, the solution was stirred at 70° C. until complete dissolution, to prepare a composition 1.

### (Production of Composition 10)

Lead iodide (368 mg) was dissolved in 1 ml of N,N-dimethylformamide, then, the solution was stirred at 70° C. until complete dissolution, to prepare a composition 10.

### (Production of Composition 2)

Methylammonium iodide (45 mg) was dissolved completely in 1 ml of 2-propanol, to prepare a composition 2.

### (Production of Composition 3)

Two parts by weight of [6, 6]-phenylC₆₁-butyric acid methyl ester (C60PCBM) (manufactured by Frontier Carbon Corporation, E100) as a fullerene derivative and 100 parts by weight of chlorobenzene as a solvent were mixed until complete dissolution. Next, the resultant solution was filtrated through a Teflon (registered trademark) filter having a pore diameter of 0.5 μm, to prepare a composition 3.

### (Production of Composition 4)

The polymer compound 1 (Mw=14000, Mw/Mn=2.7) (0.5 parts by weight) having the following repeating unit obtained in Synthesis Example 1 and 100 parts by weight of chlorobenzene as a solvent were mixed until complete dissolution, to prepare a composition 4.

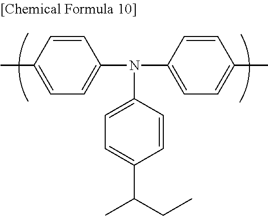

### (Production of Composition 5)

The polymer compound 4 (manufactured by Sigma Aldrich, Poly[bis(4-phenyl) (2,4,6-trimethylphenyl)amine], average Mn 7000-10000) (0.5 parts by weight) having the following repeating unit and 100 parts by weight of chlorobenzene as a solvent were mixed until complete dissolution, to prepare a composition 5.

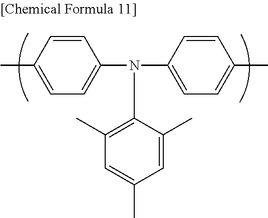

### (Production of Composition 6)

The polymer compound 2 (Mw=45000, Mw/Mn=6.7) (0.5 parts by weight) having the following repeating unit obtained in Synthesis Example 2 and 100 parts by weight of chlorobenzene as a solvent were mixed until complete dissolution, to prepare a composition 6.

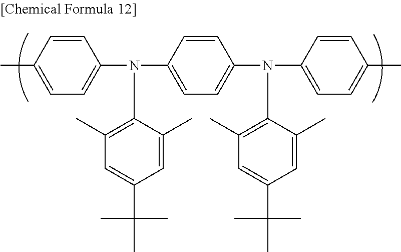

### (Production of Composition 7)

The polymer compound 5 (Mw=297000, Mw/Mn=4.1) (0.5 parts by weight) having the following repeating unit and 100 parts by weight of chlorobenzene as a solvent were mixed until complete dissolution, to prepare a composition 7. The polymer compound having the following repeating unit was synthesized according to a synthesis method described in International Publication WO 2010/026972.

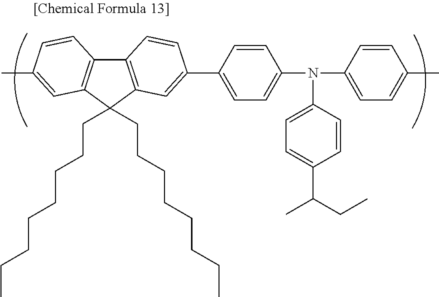

(Production of composition 8)

Spiro-MeOTAD [2,2′,7,7′-tetrakis(N,N-di-p-methoxyphenylamino)-9,9′-spiro bifluorene] (manufacture by Luminescence Technology) (1 part by weight) represented by the following structural formula and 100 parts by weight of chlorobenzene as a solvent were mixed until complete dissolution, to prepare a composition 8.

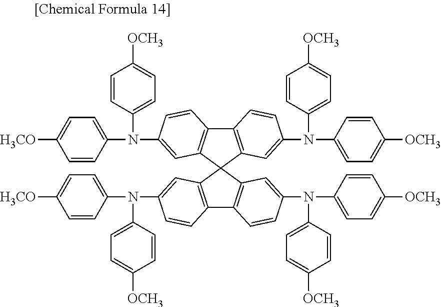 [SMILES: COc1ccc(N(c2ccc(OC)cc2)c2ccc3c(c2)C2(c4cc(N(c5ccc(OC)cc5)c5ccc(OC)cc5)ccc4-3)c3cc(N(c4ccc(OC)cc4)c4ccc(OC)cc4)ccc3-c3ccc(N(c4ccc(OC)cc4)c4ccc(OC)cc4)cc32)cc1]

### (Production of Composition 9)

A compound (A) (1 part by weight) represented by the following structural formula and 100 parts by weight of chlorobenzene as a solvent were mixed until complete dissolution, to prepare a composition 9.

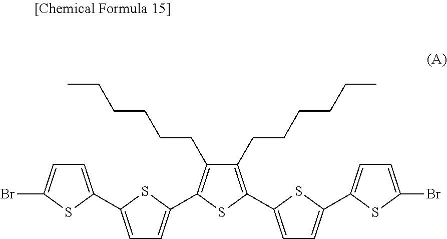 [SMILES: CCCCCCc1c(-c2ccc(-c3ccc(Br)s3)s2)sc(-c2ccc(-c3ccc(Br)s3)s2)c1CCCCCC]

### Synthesis Example 3 (Synthesis of Polymer Compound 3)

A gas in a 100 mL three-necked flask was purged with a nitrogen gas, then, a compound (A) (222 mg (0.300 mmol)) represented by the following structural formula, a compound (B) (226 mg (0.303 mmol)) represented by the following structural formula, tris(2-methoxyphenyl)phosphine [P(o-OMePh)₃] (9.5 mg (0.027 mmol)) and toluene (8.0 mL) were added, and nitrogen gas bubbling was performed for 30 minutes. Thereafter, to this were added 4.1 mg (0.005 mmol) of tris(dibenzylideneacetone)dipalladium(0) [Pd₂(dba)₃] and 3.0 mL of a sodium hydrogen carbonate aqueous solution, and the mixture was stirred at 100° C. for 30 minutes. The resultant reaction mixture was cooled down to room temperature, then, an aqueous layer was removed. To the resultant organic layer was added 10 mL of 10% acetic acid, an organic layer was washed, then, an aqueous layer was removed. To the resultant organic layer was added 10 mL of pure water, an organic layer was washed, then, an aqueous layer was removed, and this operation was repeated four times. The resultant organic layer was poured into hexane, and the precipitated solid was recovered. The resultant solid was dried, then, 15 mL of toluene was added, and the mixture was stirred at 50° C. for 15 minutes to attain dissolution thereof. The resultant toluene solution was filtrated by allowing it to pass through a silica gel/alumina column. The resultant filtrate was poured into hexane, and the precipitated solid was recovered, to obtain a polymer compound 3 (Mw=90600, Mw/Mn=3.1) (200 mg, yield: 62%).

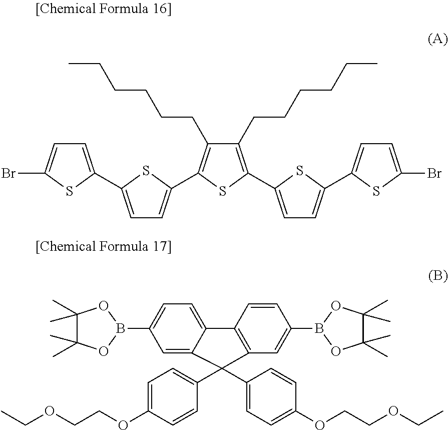 [SMILES: CCCCCCc1c(-c2ccc(-c3ccc(Br)s3)s2)sc(-c2ccc(-c3ccc(Br)s3)s2)c1CCCCCC ; CCOCCOc1ccc(C2(c3ccc(OCCOCC)cc3)c3cc(B4OC(C)(C)C(C)(C)O4)ccc3-c3ccc(B4OC(C)(C)C(C)(C)O4)cc32)cc1]

### (Production of Composition 11)

The polymer compound 3 (Mw=90600, Mw/Mn=3.1) (0.5 parts by weight) having the following repeating unit obtained in Synthesis Example 3 and 100 parts by weight of chlorobenzene as a solvent were mixed until complete dissolution, to prepare a composition 11.

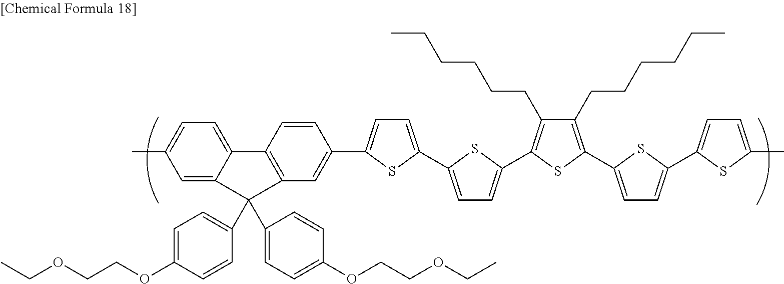

### Example 1 (Fabrication and Evaluation of Solar Battery)

A glass substrate carrying a formed ITO film functioning as an anode of a solar battery was prepared. The ITO film was one formed by a sputtering method, and its thickness was 150 nm. The glass substrate having the ITO film was subjected to an ozone UV treatment, thereby surface-treating the ITO film. Next, Plexcore PV2000 Hole Transport Ink (contained in an organic solar battery fabrication kit (PV2000 kit) manufactured by Sigma Aldrich; specifically, sulfonated polythiophene (thiophene-3-[2-(2-methoxyethoxy)ethoxy]-2,5-diyl) (S-P3MEET) 1.8% in 2-butoxyethanol:water (2:3)) was applied on the ITO film by a spin coat method, and heated in atmospheric air at 170° C. for 10 minutes, to form a hole injection layer having a film thickness of 50 nm. Next, on the hole injection layer, the composition 1 was applied at a rotation frequency of 6000 rpm by a spin coat method, and air-dried under a nitrogen gas atmosphere, to obtain an applied film of lead iodide. Next, the composition 2 was dropped onto the applied film of lead iodide, spin-coated at 6000 rpm and heated in atmospheric air at 100° C. for 10 minutes, to form an active layer. The active layer had a film thickness of about 200 nm.

Next, on the active layer, the composition 3 was spin-coated to form an electron transporting layer having a film thickness of about 60 nm. Next, on the electron transporting layer, calcium was vapor-deposited with a film thickness of 4 nm, then, silver was vapor-deposited with a film thickness of 60 nm by a vacuum vapor deposition apparatus, to fabricate a solar battery. The degree of vacuum in vapor deposition was invariably 1 to 9×10⁻³ Pa. The configuration of the resultant solar battery was 2 mm×2 mm square. The resultant solar battery was irradiated with a constant light using Solar Simulator (manufactured by Bunkoukeiki Co., Ltd., trade name: OTENTO-SUNII: AM 1.5 G filter, irradiance: 100 mW/cm²), and generating current and voltage were measured. The photoelectric conversion efficiency was 8.1%, Jsc (short circuit current density) was 14.3 mA/cm², Voc (open end voltage) was 0.93V, and FF (fill factor) was 0.61. The results are shown in Table 1.

### Example 2 (Fabrication and Evaluation of Solar Battery)

A glass substrate carrying a formed ITO film functioning as an anode of a solar battery was prepared. The ITO film was one formed by a sputtering method, and its thickness was 150 nm. The glass substrate having the ITO film was subjected to an ozone UV treatment, thereby surface-treating the ITO film. Next, Plexcore PV2000 Hole Transport Ink (contained in an organic solar battery fabrication kit (PV2000 kit) manufactured by Sigma Aldrich; specifically, sulfonated polythiophene (thiophene-3-[2-(2-methoxyethoxy)ethoxy]-2,5-diyl) (S-P3MEET) 1.8% in 2-butoxyethanol:water (2:3)) was applied on the ITO film by a spin coat method, and heated in atmospheric air at 170° C. for 10 minutes, to forma hole injection layer having a film thickness of 50 nm. Next, on the hole injection layer, the composition 4 was applied by a spin coat method, and heated in atmospheric air at 120° C. for 10 minutes, to form a hole transporting layer having a film thickness of about 10 nm. Next, on the hole transporting layer, the composition 1 was applied by a spin coat method at a rotation frequency of 6000 rpm, and air-dried under a nitrogen gas atmosphere, to obtain an applied film of lead iodide. Next, the composition 2 was dropped onto the applied film of lead iodide, spin-coated at 6000 rpm and heated in atmospheric air at 100° C. for 10 minutes, to form an active layer. The active layer had a film thickness of about 200 nm.

Next, on the active layer, the composition 3 was spin-coated to form an electron transporting layer having a film thickness of about 60 nm. Next, on the electron transporting layer, calcium was vapor-deposited with a film thickness of 4 nm, then, silver was vapor-deposited with a film thickness of 60 nm by a vacuum vapor deposition apparatus, to fabricate a solar battery. The degree of vacuum in vapor deposition was invariably 1 to 9×10⁻³ Pa. The configuration of the resultant solar battery was 2 mm×2 mm square. The resultant solar battery was irradiated with a constant light using Solar Simulator (manufactured by Bunkoukeiki Co., Ltd., trade name: OTENTO-SUNII: AM 1.5 G filter, irradiance: 100 mW/cm²), and generating current and voltage were measured. The photoelectric conversion efficiency was 9.5%, Jsc (short circuit current density) was 15.4 mA/cm², Voc (open end voltage) was 0.93V, and FF (fill factor) was 0.66. The results are shown in Table 1.

### Example 3 (Fabrication and Evaluation of Solar Battery)

A glass substrate carrying a formed ITO film functioning as an anode of a solar battery was prepared. The ITO film was one formed by a sputtering method, and its thickness was 150 nm. The glass substrate having the ITO film was subjected to an ozone UV treatment, thereby surface-treating the ITO film. Next, the composition 5 was applied on the ITO film by a spin coat method, and heated in atmospheric air at 120° C. for 10 minutes, to form a hole injection layer having a film thickness of about 20 nm. Next, the glass substrate carrying the formed hole injection layer was heated sufficiently at 70° C. on a hot plate, then, the heated substrate was placed on a spin coater, and the composition 1 was applied on the hole injection layer by a spin coat method at a rotation frequency of 6000 rpm, and air-dried under a nitrogen gas atmosphere, to obtain an applied film of lead iodide. Next, the composition 2 was dropped onto the applied film of lead iodide, spin-coated at 6000 rpm and heated in atmospheric air at 100° C. for 10 minutes, to form an active layer. The active layer had a film thickness of about 300 nm.

Next, on the active layer, the composition 3 was spin-coated to form an electron transporting layer having a film thickness of about 50 nm. Next, on the electron transporting layer, calcium was vapor-deposited with a film thickness of 4 nm, then, silver was vapor-deposited with a film thickness of 60 nm by a vacuum vapor deposition apparatus, to fabricate a solar battery. The degree of vacuum in vapor deposition was invariably 1 to 9×10⁻³ Pa. The configuration of the resultant solar battery was 2 mm×2 mm square. The resultant solar battery was irradiated with a constant light using Solar Simulator (manufactured by Bunkoukeiki Co., Ltd., trade name: OTENTO-SUNII: AM 1.5 G filter, irradiance: 100 mW/cm²), and generating current and voltage were measured. The photoelectric conversion efficiency was 12.3%, Jsc (short circuit current density) was 17.7 mA/cm², Voc (open end voltage) was 1.11V, and FF (fill factor) was 0.63. The results are shown in Table 1.

### Example 4 (Fabrication and Evaluation of Solar Battery)

A glass substrate carrying a formed ITO film functioning as an anode of a solar battery was prepared. The ITO film was one formed by a sputtering method, and its thickness was 150 nm. The glass substrate having the ITO film was subjected to an ozone UV treatment, thereby surface-treating the ITO film. Next, the composition 6 was applied on the ITO film by a spin coat method, and heated in atmospheric air at 120° C. for 10 minutes, to form a hole injection layer having a film thickness of about 25 nm. Next, the glass substrate carrying the formed hole injection layer was heated sufficiently at 70° C. on a hot plate, then, the heated substrate was placed on a spin coater, and the composition 1 was applied on the hole injection layer by a spin coat method at a rotation frequency of 6000 rpm, and air-dried under a nitrogen gas atmosphere, to obtain an applied film of lead iodide. Next, the composition 2 was dropped onto the applied film of lead iodide, spin-coated at 6000 rpm and heated in atmospheric air at 100° C. for 10 minutes, to form an active layer. The active layer had a film thickness of about 300 nm.

Next, on the active layer, the composition 3 was spin-coated to form an electron transporting layer having a film thickness of about 50 nm. Next, on the electron transporting layer, calcium was vapor-deposited with a film thickness of 4 nm, then, silver was vapor-deposited with a film thickness of 60 nm by a vacuum vapor deposition apparatus, to fabricate a solar battery. The degree of vacuum in vapor deposition was invariably 1 to 9×10⁻³ Pa. The configuration of the resultant solar battery was 2 mm×2 mm square. The resultant solar battery was irradiated with a constant light using Solar Simulator (manufactured by Bunkoukeiki Co., Ltd., trade name: OTENTO-SUNII: AM 1.5 G filter, irradiance: 100 mW/cm²), and generating current and voltage were measured. The photoelectric conversion efficiency was 6.4%, Jsc (short circuit current density) was 8.9 mA/cm², Voc (open end voltage) was 1.11V, and FF (fill factor) was 0.65. The results are shown in Table 1.

### Example 5 (Fabrication and Evaluation of Solar Battery)

A glass substrate carrying a formed ITO film functioning as an anode of a solar battery was prepared. The ITO film was one formed by a sputtering method, and its thickness was 150 nm. The glass substrate having the ITO film was subjected to an ozone UV treatment, thereby surface-treating the ITO film. Next, the composition 8 was applied on the ITO film by a spin coat method, and heated in atmospheric air at 170° C. for 10 minutes, to form a hole injection layer having a film thickness of about 40 nm. Next, the glass substrate carrying the formed hole injection layer was heated sufficiently at 70° C. on a hot plate, then, the heated substrate was placed on a spin coater, and the composition 1 was applied on the hole injection layer by a spin coat method at a rotation frequency of 6000 rpm, and air-dried under a nitrogen gas atmosphere, to obtain an applied film of lead iodide. Next, the composition 2 was dropped onto the applied film of lead iodide, spin-coated at 6000 rpm and heated in atmospheric air at 100° C. for 10 minutes, to form an active layer. The active layer had a film thickness of about 300 nm.

Next, on the active layer, the composition 3 was spin-coated to form an electron transporting layer having a film thickness of about 50 nm. Next, on the electron transporting layer, calcium was vapor-deposited with a film thickness of 4 nm, then, silver was vapor-deposited with a film thickness of 60 nm by a vacuum vapor deposition apparatus, to fabricate a solar battery. The degree of vacuum in vapor deposition was invariably 1 to 9×10⁻³ Pa. The configuration of the resultant solar battery was 2 mm×2 mm square. The resultant solar battery was irradiated with a constant light using Solar Simulator (manufactured by Bunkoukeiki Co., Ltd., trade name: OTENTO-SUNII: AM 1.5 G filter, irradiance: 100 mW/cm²), and generating current and voltage were measured. The photoelectric conversion efficiency was 6.0%, Jsc (short circuit current density) was 12.7 mA/cm², Voc (open end voltage) was 0.72 V, and FF (fill factor) was 0.65. The results are shown in Table 1.

### Example 6 (Fabrication and Evaluation of Solar Battery)

A glass substrate carrying a formed ITO film functioning as an anode of a solar battery was prepared. The ITO film was one formed by a sputtering method, and its thickness was 150 nm. The glass substrate having the ITO film was subjected to an ozone UV treatment, thereby surface-treating the ITO film. Next, the composition 4 was applied on the ITO film by a spin coat method, and heated in atmospheric air at 120° C. for 10 minutes, to form a hole injection layer having a film thickness of about 10 nm. Next, the glass substrate carrying the formed hole injection layer was heated sufficiently at 70° C. on a hot plate, then, the heated substrate was placed on a spin coater, and the composition 10 was applied on the hole injection layer by a spin coat method at a rotation frequency of 2000 rpm, and air-dried under a nitrogen gas atmosphere, to obtain an applied film of lead iodide. Next, the composition 2 was dropped onto the applied film of lead iodide, spin-coated at 6000 rpm and heated in atmospheric air at 100° C. for 10 minutes, to form an active layer. The active layer had a film thickness of about 350 nm.

Next, on the active layer, the composition 3 was spin-coated to form an electron transporting layer having a film thickness of about 50 nm. Next, on the electron transporting layer, calcium was vapor-deposited with a film thickness of 4 nm, then, silver was vapor-deposited with a film thickness of 60 nm by a vacuum vapor deposition apparatus, to fabricate a solar battery. The degree of vacuum in vapor deposition was invariably 1 to 9×10⁻³ Pa. The configuration of the resultant solar battery was 2 mm×2 mm square. The resultant solar battery was irradiated with a constant light using Solar Simulator (manufactured by Bunkoukeiki Co., Ltd., trade name: OTENTO-SUNII: AM 1.5 G filter, irradiance: 100 mW/cm²), and generating current and voltage were measured. The photoelectric conversion efficiency was 13.5%, Jsc (short circuit current density) was 17.5 mA/cm², Voc (open end voltage) was 1.10V, and FF (fill factor) was 0.70. The results are shown in Table 1.

### Example 7 (Fabrication and Evaluation of Solar Battery)

A glass substrate carrying a formed ITO film functioning as an anode of a solar battery was prepared. The ITO film was one formed by a sputtering method, and its thickness was 150 nm. The glass substrate having the ITO film was subjected to an ozone UV treatment, thereby surface-treating the ITO film. Next, the composition 5 was applied on the ITO film by a spin coat method, and heated in atmospheric air at 120° C. for 10 minutes, to form a hole injection layer having a film thickness of about 10 nm. Next, the glass substrate carrying the formed hole injection layer was heated sufficiently at 70° C. on a hot plate, then, the heated substrate was placed on a spin coater, and the composition 10 was applied on the hole injection layer by a spin coat method at a rotation frequency of 2000 rpm, and air-dried under a nitrogen gas atmosphere, to obtain an applied film of lead iodide. Next, the composition 2 was dropped onto the applied film of lead iodide, spin-coated at 6000 rpm and heated in atmospheric air at 100° C. for 10 minutes, to form an active layer. The active layer had a film thickness of about 350 nm.

Next, on the active layer, the composition 3 was spin-coated to form an electron transporting layer having a film thickness of about 50 nm. Next, on the electron transporting layer, calcium was vapor-deposited with a film thickness of 4 nm, then, silver was vapor-deposited with a film thickness of 60 nm by a vacuum vapor deposition apparatus, to fabricate a solar battery. The degree of vacuum in vapor deposition was invariably 1 to 9×10⁻³ Pa. The configuration of the resultant solar battery was 2 mm×2 mm square. The resultant solar battery was irradiated with a constant light using Solar Simulator (manufactured by Bunkoukeiki Co., Ltd., trade name: OTENTO-SUNII: AM 1.5 G filter, irradiance: 100 mW/cm²), and generating current and voltage were measured. The photoelectric conversion efficiency was 14.6%, Jsc (short circuit current density) was 18.3 mA/cm², Voc (open end voltage) was 1.09V, and FF (fill factor) was 0.70. The results are shown in Table 1.

### Example 8 (Fabrication and Evaluation of Solar Battery)

A glass substrate carrying a formed ITO film functioning as an anode of a solar battery was prepared. The ITO film was one formed by a sputtering method, and its thickness was 150 nm. The glass substrate having the ITO film was subjected to an ozone UV treatment, thereby surface-treating the ITO film. Next, the composition 6 was applied on the ITO film by a spin coat method, and heated in atmospheric air at 120° C. for 10 minutes, to form a hole injection layer having a film thickness of about 10 nm. Next, the glass substrate carrying the formed hole injection layer was heated sufficiently at 70° C. on a hot plate, then, the heated substrate was placed on a spin coater, and the composition 10 was applied on the hole injection layer by a spin coat method at a rotation frequency of 2000 rpm, and air-dried under a nitrogen gas atmosphere, to obtain an applied film of lead iodide. Next, the composition 2 was dropped onto the applied film of lead iodide, spin-coated at 6000 rpm and heated in atmospheric air at 100° C. for 10 minutes, to form an active layer. The active layer had a film thickness of about 350 nm.

Next, on the active layer, the composition 3 was spin-coated to form an electron transporting layer having a film thickness of about 50 nm. Next, on the electron transporting layer, calcium was vapor-deposited with a film thickness of 4 nm, then, silver was vapor-deposited with a film thickness of 60 nm by a vacuum vapor deposition apparatus, to fabricate a solar battery. The degree of vacuum in vapor deposition was invariably 1 to 9×10⁻³ Pa. The configuration of the resultant solar battery was 2 mm×2 mm square. The resultant solar battery was irradiated with a constant light using Solar Simulator (manufactured by Bunkoukeiki Co., Ltd., trade name: OTENTO-SUNII: AM 1.5 G filter, irradiance: 100 mW/cm²), and generating current and voltage were measured. The photoelectric conversion efficiency was 14.2%, Jsc (short circuit current density) was 18.1 mA/cm², Voc (open end voltage) was 1.06V, and FF (fill factor) was 0.74. The results are shown in Table 1.

### Example 9 (Fabrication and Evaluation of Solar Battery)

A glass substrate carrying a formed ITO film functioning as an anode of a solar battery was prepared. The ITO film was one formed by a sputtering method, and its thickness was 150 nm. The glass substrate having the ITO film was subjected to an ozone UV treatment, thereby surface-treating the ITO film. Next, the composition 8 was applied on the ITO film by a spin coat method, and heated in atmospheric air at 120° C. for 10 minutes, to form a hole injection layer having a film thickness of about 20 nm. Next, the glass substrate carrying the formed hole injection layer was heated sufficiently at 70° C. on a hot plate, then, the heated substrate was placed on a spin coater, and the composition 10 was applied on the hole injection layer by a spin coat method at a rotation frequency of 2000 rpm, and air-dried under a nitrogen gas atmosphere, to obtain an applied film of lead iodide. Next, the composition 2 was dropped onto the applied film of lead iodide, spin-coated at 6000 rpm and heated in atmospheric air at 100° C. for 10 minutes, to form an active layer. The active layer had a film thickness of about 350 nm.

Next, on the active layer, the composition 3 was spin-coated to form an electron transporting layer having a film thickness of about 50 nm. Next, on the electron transporting layer, calcium was vapor-deposited with a film thickness of 4 nm, then, silver was vapor-deposited with a film thickness of 60 nm by a vacuum vapor deposition apparatus, to fabricate a solar battery. The degree of vacuum in vapor deposition was invariably 1 to 9×10⁻³ Pa. The configuration of the resultant solar battery was 2 mm×2 mm square. The resultant solar battery was irradiated with a constant light using Solar Simulator (manufactured by Bunkoukeiki Co., Ltd., trade name: OTENTO-SUNII: AM 1.5 G filter, irradiance: 100 mW/cm²), and generating current and voltage were measured. The photoelectric conversion efficiency was 10.3%, Jsc (short circuit current density) was 16.4 mA/cm², Voc (open end voltage) was 1.03V, and FF (fill factor) was 0.61. The results are shown in Table 1.

### Example 10 (Fabrication and Evaluation of Solar Battery)

A glass substrate carrying a formed ITO film functioning as an anode of a solar battery was prepared. The ITO film was one formed by a sputtering method, and its thickness was 150 nm. The glass substrate having the ITO film was subjected to an ozone UV treatment, thereby surface-treating the ITO film. Next, the composition 9 was applied on the ITO film by a spin coat method, and dried in atmospheric air at room temperature, to form a hole injection layer having a film thickness of about 10 nm. Next, the glass substrate carrying the formed hole injection layer was heated sufficiently at 70° C. on a hot plate, then, the heated substrate was placed on a spin coater, and the composition 10 was applied on the hole injection layer by a spin coat method at a rotation frequency of 2000 rpm, and air-dried under a nitrogen gas atmosphere, to obtain an applied film of lead iodide. Next, the composition 2 was dropped onto the applied film of lead iodide, spin-coated at 6000 rpm and heated in atmospheric air at 100° C. for 10 minutes, to form an active layer. The active layer had a film thickness of about 350 nm.

Next, on the active layer, the composition 3 was spin-coated to form an electron transporting layer having a film thickness of about 50 nm. Next, on the electron transporting layer, calcium was vapor-deposited with a film thickness of 4 nm, then, silver was vapor-deposited with a film thickness of 60 nm by a vacuum vapor deposition apparatus, to fabricate a solar battery. The degree of vacuum in vapor deposition was invariably 1 to 9×10⁻³ Pa. The configuration of the resultant solar battery was 2 mm×2 mm square. The resultant solar battery was irradiated with a constant light by Solar Simulator (manufactured by Yamashita Denso Corporation, trade name: YSS-80A: AM 1.5 G filter, irradiance: 100 mW/cm²), and generating current and voltage were measured. The photoelectric conversion efficiency was 10.3%, Jsc (short circuit current density) was 17.3 mA/cm², Voc (open end voltage) was 0.98 V, and FF (fill factor) was 0.61. The results are shown in Table 1.

### Example 11 (Fabrication and Evaluation of Solar Battery)

A glass substrate carrying a formed ITO film functioning as an anode of a solar battery was prepared. The ITO film was one formed by a sputtering method, and its thickness was 150 nm. The glass substrate having the ITO film was subjected to an ozone UV treatment, thereby surface-treating the ITO film. Next, the composition 11 was applied on the ITO film by a spin coat method, and heated in atmospheric air at 120° C. for 10 minutes, to form a hole injection layer having a film thickness of about 10 nm. Next, the glass substrate carrying the formed hole injection layer was heated sufficiently at 70° C. on a hot plate, then, the heated substrate was placed on a spin coater, and the composition 10 was applied on the hole injection layer by a spin coat method at a rotation frequency of 2000 rpm, and air-dried under a nitrogen gas atmosphere, to obtain an applied film of lead iodide. Next, the composition 2 was dropped onto the applied film of lead iodide, spin-coated at 6000 rpm and heated in atmospheric air at 100° C. for 10 minutes, to form an active layer. The active layer had a film thickness of about 350 nm.

Next, on the active layer, the composition 3 was spin-coated to form an electron transporting layer having a film thickness of about 50 nm. Next, on the electron transporting layer, calcium was vapor-deposited with a film thickness of 4 nm, then, silver was vapor-deposited with a film thickness of 60 nm by a vacuum vapor deposition apparatus, to fabricate a solar battery. The degree of vacuum in vapor deposition was invariably 1 to 9×10⁻³ Pa. The configuration of the resultant solar battery was 2 mm×2 mm square. The resultant solar battery was irradiated with a constant light by Solar Simulator (manufactured by Yamashita Denso Corporation, trade name: YSS-80A: AM 1.5 G filter, irradiance: 100 mW/cm²), and generating current and voltage were measured. The photoelectric conversion efficiency was 11.8%, Jsc (short circuit current density) was 17.6 mA/cm², Voc (open end voltage) was 1.06V, and FF (fill factor) was 0.63. The results are shown in Table 1.

### Comparative Example 1 (Fabrication and Evaluation of Solar Battery)

A glass substrate carrying a formed ITO film functioning as an anode of a solar battery was prepared. The ITO film was one formed by a sputtering method, and its thickness was 150 nm. The glass substrate having the ITO film was subjected to an ozone UV treatment, thereby surface-treating the ITO film. Next, a PEDOT:PSS solution (manufactured by Heraeus, CleviosP VP AI4083) was applied on the ITO film by a spin coat method, and heated in atmospheric air at 120° C. for 10 minutes, to form a hole injection layer having a film thickness of 50 nm. Next, on the hole injection layer, the composition 1 was applied at a rotation frequency of 6000 rpm by a spin coat method, and air-dried under a nitrogen gas atmosphere, to obtain an applied film of lead iodide. Next, the composition 2 was dropped onto the applied film of lead iodide, spin-coated at 6000 rpm and heated in atmospheric air at 100° C. for 10 minutes, to form an active layer. The active layer had a film thickness of about 200 nm.

Next, on the active layer, the composition 3 was spin-coated to form an electron transporting layer having a film thickness of about 60 nm. Next, on the electron transporting layer, calcium was vapor-deposited with a film thickness of 4 nm, then, silver was vapor-deposited with a film thickness of 60 nm by a vacuum vapor deposition apparatus, to fabricate a solar battery. The degree of vacuum in vapor deposition was invariably 1 to 9×10⁻³ Pa. The configuration of the resultant solar battery was 2 mm×2 mm square. The resultant solar battery was irradiated with a constant light using Solar Simulator (manufactured by Bunkoukeiki Co., Ltd., trade name: OTENTO-SUNII: AM 1.5 G filter, irradiance: 100 mW/cm²), and generating current and voltage were measured. The photoelectric conversion efficiency was 2.94%, Jsc (short circuit current density) was 4.7 mA/cm², Voc (open end voltage) was 0.97V, and FF (fill factor) was 0.65. The results are shown in Table 1.

### Comparative Example 2 (Fabrication and Evaluation of Solar Battery)

A glass substrate carrying a formed ITO film functioning as an anode of a solar battery was prepared. The ITO film was one formed by a sputtering method, and its thickness was 150 nm. The glass substrate having the ITO film was subjected to an ozone UV treatment, thereby surface-treating the ITO film. Next, the composition 7 was applied on the ITO film by a spin coat method, and dried in vacuum, to form a hole injection layer having a film thickness of about 30 nm. Next, the glass substrate carrying the formed hole injection layer was heated sufficiently at 70° C. on a hot plate, then, the heated substrate was placed on a spin coater, and the composition 1 was applied on the hole injection layer by a spin coat method at a rotation frequency of 6000 rpm, and air-dried under a nitrogen gas atmosphere, to obtain an applied film of lead iodide. Next, the composition 2 was dropped onto the applied film of lead iodide, spin-coated at 6000 rpm and heated in atmospheric air at 100° C. for 10 minutes, to form an active layer. The active layer had a film thickness of about 300 nm.

Next, on the active layer, the composition 3 was spin-coated to form an electron transporting layer having a film thickness of about 50 nm. Next, on the electron transporting layer, calcium was vapor-deposited with a film thickness of 4 nm, then, silver was vapor-deposited with a film thickness of 60 nm by a vacuum vapor deposition apparatus, to fabricate a solar battery. The degree of vacuum in vapor deposition was invariably 1 to 9×10⁻³ Pa. The configuration of the resultant solar battery was 2 mm×2 mm square. The resultant solar battery was irradiated with a constant light using Solar Simulator (manufactured by Bunkoukeiki Co., Ltd., trade name: OTENTO-SUNII: AM 1.5 G filter, irradiance: 100 mW/cm²), and generating current and voltage were measured. The photoelectric conversion efficiency was 4.5%, Jsc (short circuit current density) was 14.6 mA/cm², Voc (open end voltage) was 1.04 V, and FF (fill factor) was 0.47. The results are shown in Table 1.

### (Measurement of Residual Film Rate)

On a 1-inch square substrate, Plexcore PV2000 Hole Transport Ink (contained in an organic solar battery fabrication kid (PV2000 kit) manufactured by Sigma Aldrich, as described above) was applied by a spin coat method, and heated in atmospheric air at 170° C. for 10 minutes, to form an applied film having a film thickness of 50 nm. Next, water was placed in the form of meniscus on this applied film, and 30 seconds after, the film was spun at 4000 rpm to fling away water. The applied film had a residual film rate of 100%.

On a 1-inch square substrate, a PEDOT:PSS solution (manufactured by Heraeus, CleviosP VP AI4083) was applied by a spin coat method, and heated in atmospheric air at 120° C. for 10 minutes, to form an applied film having a film thickness of 50 nm. Next, water was placed in the form of meniscus on this applied film, and 30 seconds after, the film was spun at 4000 rpm to fling away water. The applied film had a residual film rate of 0%.

On a 1-inch square substrate, the composition 4 was applied by a spin coat method, and heated in atmospheric air at 120° C. for 10 minutes, to form an applied film having a film thickness of about 10 nm. Next, water was placed in the form of meniscus on this applied film, and 30 seconds after, the film was spun at 4000 rpm to fling away water. The applied film had a residual film rate of 100%.

On a 1-inch square substrate, the composition 5 was applied by a spin coat method, and heated in atmospheric air at 120° C. for 10 minutes, to form an applied film having a film thickness of about 20 nm. Next, water was placed in the form of meniscus on this applied film, and 30 seconds after, the film was spun at 4000 rpm to fling away water. The applied film had a residual film rate of 100%.

On a 1-inch square substrate, the composition 5 was applied by a spin coat method, and heated in atmospheric air at 120° C. for 10 minutes, to form an applied film having a film thickness of about 10 nm. Next, water was placed in the form of meniscus on this applied film, and 30 seconds after, the film was spun at 4000 rpm to fling away water. The applied film had a residual film rate of 100%.

On a 1-inch square substrate, the composition 6 was applied by a spin coat method, and heated in atmospheric air at 120° C. for 10 minutes, to form an applied film having a film thickness of about 25 nm. Next, water was placed in the form of meniscus on this applied film, and 30 seconds after, the film was spun at 4000 rpm to fling away water. The applied film had a residual film rate of 100%.

On a 1-inch square substrate, the composition 6 was applied by a spin coat method, and heated in atmospheric air at 120° C. for 10 minutes, to form an applied film having a film thickness of about 10 nm. Next, water was placed in the form of meniscus on this applied film, and 30 seconds after, the film was spun at 4000 rpm to fling away water. The applied film had a residual film rate of 100%.

On a 1-inch square substrate, the composition 7 was applied by a spin coat method, and heated in atmospheric air at 120° C. for 10 minutes, to form an applied film having a film thickness of about 30 nm. Next, water was placed in the form of meniscus on this applied film, and 30 seconds after, the film was spun at 4000 rpm to fling away water. The applied film had a residual film rate of 100%.

On a 1-inch square substrate, the composition 8 was applied by a spin coat method, and heated in atmospheric air at 170° C. for 10 minutes, to form an applied film having a film thickness of about 40 nm. Next, water was placed in the form of meniscus on this applied film, and 30 seconds after, the film was spun at 4000 rpm to fling away water. The applied film had a residual film rate of 100%.

On a 1-inch square substrate, the composition 8 was applied by a spin coat method, and heated in atmospheric air at 120° C. for 10 minutes, to form an applied film having a film thickness of about 20 nm. Next, water was placed in the form of meniscus on this applied film, and 30 seconds after, the film was spun at 4000 rpm to fling away water. The applied film had a residual film rate of 100%.

On a 1-inch square substrate, the composition 9 was applied by a spin coat method, and dried in atmospheric air at room temperature, to form an applied film having a film thickness of about 10 nm. Next, water was placed in the form of meniscus on this applied film, and 30 seconds after, the film was spun at 4000 rpm to fling away water. The applied film had a residual film rate of 100%.

On a 1-inch square substrate, the composition 11 was applied by a spin coat method, and heated in atmospheric air at 120° C. for 10 minutes, to form an applied film having a film thickness of about 10 nm. Next, water was placed in the form of meniscus on this applied film, and 30 seconds after, the film was spun at 4000 rpm to fling away water. The applied film had a residual film rate of 100%.

TABLE 1

| | | | | hole | |
|---|---|---|---|---|---|
| | hole injection layer | | | trans- | photo- |
| | | film | residual | porting | electric |
| | | thick- | film | layer | conversion |
| | material | ness | rate | material | efficiency |
| Example 1 | S-P3MEET | 50 nm | 100% | — | 8.1% |
| Example 2 | S-P3MEET | 50 nm | 100% | polymer | 9.5% |
| | | | | compound | |
| | | | | 1 | |
| | | | | (compo- | |
| | | | | sition | |
| | | | | 4) | |
| Example 3 | polymer | 20 nm | 100% | — | 12.3% |
| | compound 4 | | | | |
| | (composition 5) | | | | |
| Example 4 | polymer | 25 nm | 100% | — | 6.4% |
| | compound 2 | | | | |
| | (composition 6) | | | | |
| Example 5 | Spiro-MeOTAD | 40 nm | 100% | — | 6.0% |
| | (composition 8) | | | | |
| Example 6 | polymer | 10 nm | 100% | — | 13.5% |
| | compound 1 | | | | |
| | (composition 4) | | | | |
| Example 7 | polymer | 10 nm | 100% | — | 14.6% |
| | compound 4 | | | | |
| | (composition 5) | | | | |
| Example 8 | polymer | 10 nm | 100% | — | 14.2% |
| | compound 2 | | | | |
| | (composition 6) | | | | |
| Example 9 | Spiro-MeOTAD | 20 nm | 100% | — | 10.3% |
| | (composition 8) | | | | |
| Example 10 | a compound (A) | 10 nm | 100% | — | 10.3% |
| | (composition 9) | | | | |
| Example 11 | polymer | 10 nm | 100% | — | 11.8% |
| | compound 3 | | | | |
| | (composition 11) | | | | |
| Comparative | PEDOT/PSS | 50 nm | 0% | — | 2.94% |
| Example 1 | | | | | |
| Comparative | polymer | 30 nm | 100% | — | 4.5% |
| Example 2 | compound 5 | | | | |
| | (composition 7) | | | | |

### INDUSTRIAL APPLICABILITY

By the photoelectric conversion device using a water-insoluble hole injection layer of the present invention, high photoelectric conversion efficiency can be obtained.

1. A photoelectric conversion device having an anode, a cathode, an active layer containing a perovskite compound disposed between the anode and the cathode, and a hole injection layer disposed between the anode and the active layer, wherein
the hole injection layer is a layer having a residual film rate of 80% or more in measurement of the residual film rate after a water rinse treatment shown below, and
the material of the hole injection layer is at least one material selected from the group consisting of polythiophene and derivatives thereof, aromatic amine compounds, and polymer compounds having an aromatic amine residue containing a phenyl group having at least three substituents as a repeating unit:
<Method of measurement of residual film rate after water rinse treatment>
on a 1-inch square substrate, a film is formed by a spin coat method so at to give the same film thickness as in the case of film formation as the hole injection layer in the photoelectric conversion device, then, a water rinse treatment in which water is placed in the form of meniscus on the film, allowed to stand still for 30 seconds, then, the film is spun at 4000 rpm to fling away water is conducted,
the film thicknesses before and after the water rinse treatment are measured by a contact-type film thickness meter, and (film thickness after water rinse treatment)/(film thickness before water rinse treatment)×100(%) is defined as the residual film rate after the water rinse treatment.

2. A photoelectric conversion device having an anode, a cathode, an active layer containing a perovskite compound disposed between the anode and the cathode, and a hole injection layer disposed between the anode and the active layer, wherein
the hole injection layer is a layer having a residual film rate of 80% or more in measurement of the residual film rate after a water rinse treatment shown below,
the material of the hole injection layer is at least one material selected from the group consisting of aromatic amine compounds and polymer compounds having an aromatic amine residue as a repeating unit, and
the thickness of the hole injection layer is 15 nm or less:
<Method of measurement of residual film rate after water rinse treatment>
on a 1-inch square substrate, a film is formed by a spin coat method so at to give the same film thickness as in the case of film formation as the hole injection layer in the photoelectric conversion device, then, a water rinse treatment in which water is placed in the form of meniscus on the film, allowed to stand still for 30 seconds, then, the film is spun at 4000 rpm to fling away water is conducted,
the film thicknesses before and after the water rinse treatment are measured by a contact-type film thickness meter, and (film thickness after water rinse treatment)/(film thickness before water rinse treatment)×100(%) is defined as the residual film rate after the water rinse treatment.

3. The photoelectric conversion device according to claim 1, having a constitution in which the supporting substrate, the anode, the hole injection layer, the active layer and the cathode are laminated in this order.

4. The photoelectric conversion device according to claim 1, further having an electron transporting layer disposed between the active layer and the cathode.

5. The photoelectric conversion device according to claim 4, wherein the electron transporting layer is a layer formed by applying an application liquid containing at least one material selected from the group consisting of fullerenes and fullerene derivatives.

6. The photoelectric conversion device according to claim 1, further having a hole transporting layer disposed between the hole injection layer and the active layer.

7. The photoelectric conversion device according to claim 1, wherein the active layer is a layer formed by an application method.

8. An organic optical sensor having the photoelectric conversion device according to claim 1.

9. A method of producing a photoelectric conversion device having a supporting substrate, an anode, a cathode, an active layer containing a perovskite compound disposed between the anode and the cathode, and a hole injection layer disposed between the anode and the active layer,
the method comprising
a step of forming a hole injection layer on an anode formed on a supporting substrate, and
a step of forming an active layer on the hole injection layer,
wherein
the hole injection layer is a layer having a residual film rate of 80% or more in measurement of the residual film rate after a water rinse treatment shown below, and
the material of the hole injection layer is at least one material selected from the group consisting of polythiophene and derivatives thereof, aromatic amine compounds, and polymer compounds having an aromatic amine residue containing a phenyl group having at least three substituents as a repeating unit:
<Method of measurement of residual film rate after water rinse treatment>
on a 1-inch square substrate, a film is formed by a spin coat method so at to give the same film thickness as in the case of film formation as the hole injection layer in the photoelectric conversion device, then, a water rinse treatment in which water is placed in the form of meniscus on the film, allowed to stand still for 30 seconds, then, the film is spun at 4000 rpm to fling away water is conducted
the film thicknesses before and after the water rinse treatment are measured by a contact-type film thickness meter, and (film thickness after water rinse treatment)/(film thickness before water rinse treatment)×100(%) is defined as the residual film rate after the water rinse treatment.

10. A method of producing a photoelectric conversion device having a supporting substrate, an anode, a cathode, an active layer containing a perovskite compound disposed between the anode and the cathode, and a hole injection layer disposed between the anode and the active layer,
the method comprising
a step of forming a hole injection layer on an anode formed on a supporting substrate, and
a step of forming an active layer on the hole injection layer,
wherein
the hole injection layer is a layer having a residual film rate of 80% or more in measurement of the residual film rate after a water rinse treatment shown below,
the material of the hole injection layer is at least one material selected from the group consisting of aromatic amine compounds and polymer compounds having an aromatic amine residue as a repeating unit, and
the thickness of the hole injection layer is 15 nm or less:
<Method of measurement of residual film rate after water rinse treatment>
on a 1-inch square substrate, a film is formed by a spin coat method so at to give the same film thickness as in the case of film formation as the hole injection layer in the photoelectric conversion device, then, a water rinse treatment in which water is placed in the form of meniscus on the film, allowed to stand still for 30 seconds, then, the film is spun at 4000 rpm to fling away water is conducted,
the film thicknesses before and after the water rinse treatment are measured by a contact-type film thickness meter, and (film thickness after water rinse treatment)/(film thickness before water rinse treatment)×100(%) is defined as the residual film rate after the water rinse treatment.
